(19) United States
(12) Patent Application Publication
(10) Pub. No.: US 2021/0341411 A1
(43) Pub. Date: Nov. 4, 2021

(54) Room-temperature Topological Superconductive/Mem-element Protein Moonlighting Network Devices of Making and Applications Thereto

(71) Applicant: Ellen T. Chen, Rockville, MD (US)

(72) Inventor: Ellen T. Chen, Rockville, MD (US)

(21) Appl. No.: 17/306,736

(22) Filed: May 3, 2021

Related U.S. Application Data
(63) Continuation-in-part of application No. 15/984,349, filed on May 19, 2018, now Pat. No. 11,041,843.
(60) Provisional application No. 63/041,902, filed on Jun. 20, 2020.

(51) Int. Cl. G01N 27/327; G01N 27/48; G01N 27/416; H01L 39/12; H01L 39/22

(52) U.S. Cl. CPC G01N 27/3276; G01N 27/48; H01L 39/223; H01L 39/121; G01N 27/4161

(57) ABSTRACT

Topological superconductive and memristive nanostructured toroidal-tower array devices are invented for direct electrochemical sensing of multiple biomarkers based on the biomimetic glucose . . . pyruvate . . . acetyl CoA (ACoA) fuel energy pathway of mitochondria. The device comprises flexible fractional Josephson junctions (FFJJ) made of innate organometallic protein cross-linked with conductive polymers forming a first layer membrane on the electrode surface, a medium comprising of glucose and acetyl CoA (ACoA) molecules (as the GA medium), serves as an insulator or a conductor when pyruvate molecules activated the medium, and the second layer comprising of an innate Heat Shock Protein (HSP) cross-linked with the similar polymers on top of the first layer. Cooper-pairs reentry between the state of superconductivity at room temperature and the memristive state are enabled through a molecular “Valve” GA medium activated by a biomarker to switch the electron move in a 3D horizontal-vertical pathway from low Josephson frequency to high Josephson frequency, enabled the device to direct sensitive and quantitative sensing multiple-biomarkers without antibody or labeling, wherein many applications are discussed.

### CROSS-REFERENCE TO RELATED APPLICATIONS

This patent application is a U.S. Continuation in Part (CIP) Non-Provisional patent Application. This patent application claims the benefit of U.S. Provisional Patent Application Ser. No. 62/339,829 filed on May 21, 2016; U.S. non provisional application for extended missing parts pilot program No. 15/602,103, filed on May 23, 2017, and the benefit of a provisional application U.S. Ser. No. 63/041,902 in the title of Superconductive/Mem-element Nanostructured Array Devices of Making and Its Applications for Direct Sensing of Multiple Biomarkers Thereto filed on Jun. 20, 2020. The entire disclosure of the prior patent application Ser. No. 15/984, 349, 15/602,103, 62/339,829 and 63/041,902 is hereby incorporated by references, as is set forth herein in its entirety.

### FIELD OF THE INVENTION

The invention relates to the field of electrochemical sensors, in particular, to a device having both characteristics in memristor/memcapacitor for direct sensing of endotoxin activities of single E. Coli cell and other proteins in biological substances.

The present invention in the title of Room-temperature Topological Superconductive/Mem-element Protein Moonlighting Network Devices of Making and Applications Thereto, in particular, relates to the field of superconductor, in particular, a device has functions in superconductivity and multiple-biomarker sensing, which have both characteristics in superconductive and memristive at room-temperature, emphasizing Cooper-pairs' quantum conductance is switchable under the promotion of a biomarker and a molecular insulator platform “valve” working together switches between quantum conductance and memristive states.

### BACKGROUND OF THE INVENTION

Lipopolysaccharide (LPS) is a common endotoxin from E. Coli bacteria, and is the major source causing infectious diseases over 20 million people worldwide. LPS is a major contaminant found in commercially available proteins, and it is also the major contaminate in biological ingredients in drugs and injectables, because even small amount of endotoxin can cause side effects such as endotoxic shock, injury, and even death; therefore a strengthened standard of drug purity is needed. However, removing LPS from pharmaceutical products, for intravenous application to 5 endotoxin units (EU) per kg of body weight per hr, is a challenge to researchers who thought this standard is unachievable [1-2]. E. Coli bacteria covers 75% its outer layer membrane with gram-negative exotoxin LPS, and it stimulates the host's immune response of cytokines [3-4]. Recently, researchers reported LPS penetrates the gut-immune-barrier (GIB) causing liver infection [5]; LPS leaking from the tight junction in the gut membrane into the blood stream cause many diseases, autism, obesity, diabetes, Alzheimer's, chronic pain, and inflammation [6-10]. Furthermore, LPS can break the blood-milk barrier into the milk and may cause harm, as reported from collected cow milk, which was compromised by LPS, and may have caused mastitis [11]. A recently published paper reported human milk offers an advantage to correlate positively with gut microbiota and to maintain healthy oligosaccharide (HMO) isomers which are specific to human milk and that are necessary in the newborn infant's gut in the first week [12].

A paramount challenge was put on the researchers and industry as a whole for improving the LPS detection methods with more simplified procedure, more accuracy and precision, faster, and more affordable options. Because previously, a lack of sensitivity associated with the protein interference plus time consuming antibody and tracer assays hampered the ability to realize the unmet goals and fulfill these needs.

It is a well-accepted fact that breast-feeding offers more benefits for human babies' growth in nutritional and immune defense over cow milk [13-15], and it has been strongly recommended, as published by the World Health Organization [15]. We found very few tests or sensors, if any, to assess the energy outcomes at different neuronal synapse frequencies, such as slow-wave-sleeping and fast gamma frequency, between breast-feeding using human milk as compared with feeding organic cow milk in the presence of LPS challenge. We believe that this testing is important because not only it will increase our knowledge, but also it will provide first hand convincing evidence for preferring human milk for feeding infants in regards to the energy requirement for mental and physical development of infants. Our goal for this project is to develop a nanostructured memcapacitor/memristor sensor for antibody-free, reagent-free direct measurement of pg LPS, and to assess the energy outcome comparing human milk with cow milk. The intention is that the memcapacitor/memristor device represents, in concept, a baby's single neuron to “feel” the energy gain or loss in the presence of LPS. This project is based on our prior experience in using the memristor/memcapacitor to mimic hippocampus-neocortex neuronal network circuitry [16-20].

Acetyl co-enzyme A (AcCoA) is a leading substrate in a large variety of enzyme-catalyzed reactions, such as for choline acetyltransferase (CHAT) and acetylcholinesterase (ACHE) [21-25]. Szutowicz's group emphasized that AcCoA is the key factor for the survival or death of cholinergic neurons in course of neurodegenerative diseases [25]. Ivan Gout's group emphasized that the level of AcCoA is crucial to early embryonic development [26]. AcCoA is a thioester derived from catabolism of all major carbon fuels. AcCoA may play a role in the energy production, metabolism, memory, cell proliferation and early childhood development, and it is central to biological acetylation reactions. AcCoA deficiency leads to many diseases, such as diabetes, cancer, coronary disease, autism, Alzheimer's, and sudden infant death syndrome. Abnormality of CHAT activity may lead to these diseases because CHAT represents the most specific cholinergic marker in the CNS [27-28] and the spatial temporal manifestation of CHAT has been examined at both the protein and mRNA levels in different tissues of various species [28].

Furthermore, reports revealed that the virus replications of West Nile virus (WNV), the neurotropic flavivirus that is transmitted by mosquito bites causing meningitis and encephalitis in humans [29], involved the carboxylation of AcCoA to malonyl CoA through AcCoA carboxylase [29]. Therefore, sensitive quantitation of the CHAT activity, in terms of monitoring the changes of substrate AcCoA in biological specimens, is on demand for monitoring and diagnosing various diseases.

Challenges exist for providing a non-enzymatic label-free, reagent-less detection device for the direct detection of AcCoA with rapid detection time, free specimen preparation, and pM high sensitivity are paramount in order to avoid time-consuming assays and protein interferences. Many native enzymatic methods reported to detect AcCoA have the concentration range between mM to such as the CoA cycling method [23], the carbon radioactive tracer labeling method [30-31], and the gas chromatography-mass spectrometry method [32]. The HPLC antibody method can reach to 0.1 μM level of AcCoA [26]. In view of the drawbacks of these methods, none of these methods can provide adequate sensitivity in pM level and the short testing time needed for testing AcCoA inside of the mitochondria cell when newborns consume human milk compared with that of cow milk in order to monitor the quality of the milk for babies.

It is well accepted that breast-feeding offers more benefits for human babies' growth in nutritional content and immune defense support over that of cow milk consumption [13-15] and it is a strong recommendation published by the World Health Organization [15]. However, to actively pursue real-time monitoring of breastfeeding and obtain the preliminary data using an innovative device is not practically feasible now. The goal of this project is to develop a nanostructured memcapacitor/memristor sensor for antibody-free, reagent-less direct measure pM AcCoA at different frequencies to assess the energy outcome comparing human milk with cow milk without protein interference and in a real-time and sensitive manner. The memcapacitor/memristor device will represent, in concept, a human infant single brain neuron's ability to “feel” or sense the energy gain or loss that is due to the presence of AcCoA signaling with the biomimetic CHAT of the sensor membrane in a biological specimen. This project is based on our prior experience in memristor/memcapacitor to mimic hippocampus-neocortex neuronal network circuitry [16-20].

### Following is the Background of the CIP Invention

Moonlighting proteins are unique as they perform more unrelated functions [1-4]. Moonlighting proteins challenge the typical expectation that enzymes only have one defined function and stay in a location not mobile. Biomarkers identified for screening diseases such as diabetes, Alzheimer's, breast cancer, lung and prostate cancer, cardiomyocytes, urinary tract infection, and pneumonia are usually associated with multiple protein-protein interactions (PPI), formed networks because research revealed over 80% proteins do not operate alone but in complexes [1-4].

Christopher Overall's group reported matrix metalloproteinase (MMP) has a significant role in the PPI network associated with several diseases [3]. For example, diabetes' hyperglycemia activate MMP-2 concentration in the mitochondrial cell, and decreases the Heat Shock Protein (HSP60)'s concentration, which leads to disturbing the mitochondrial gap membrane potential, causes mitochondria cell dysfunction. Therefore, protein MMP-2 networks with HSP60 in the presence of biomarker hyperglycemia contributes to myocardial dysfunction was reported [3,5].

MMP is a family of zinc-dependent endopeptidases. The enzymes play a key role in human health for promoting newborn growth, nervous system growth, as well as in promoting various human diseases, such as cancer invasion, osteoarthritis, tissue destruction, diabetes, coronary malfunction, epilepsy and Alzheimer's [6-9]. MMP's major role is to degrade the extracellular matrix as a double-edged sword, as well as a biomarker to network intracellular with HSP60 and HSP70. MMP-2 has been identified as a critical biomarker for diagnosing, monitoring and predicting multiple types of human diseases [9-14]. HSP's major roles as molecular chaperons to help refold stressed proteins also acted as immunomodulates whose capability is to transform the anti-inflammatory property when the HSP concentrations are low to the pro-inflammatory property when HSP concentrations are high [15-16].

Our group's prior work demonstrated the biomarker ATP molecules were able to be stabilized in the Tris buffer with modified cyclodextrin (CD) media promoted a long-range Direct Electron-transfer (DET) favorable status led ATP molecules directly communicate in an activated 3D-cage biomimetic MMP-2 with an HSP60-like tall cylinder membrane fabricated by a direct deposition method without cysteine, that stimulated superconductivity at the gamma frequency 60 Hz over a range from 400 aM to 2 mM without causing any extracellular ATP hydrolysis using the human milk compared with the organic milk samples [17-18]. Upon that experiences, a hypothesis has risen, to fabricate an innate MMP-2/HSP60 network protein device using similar components cross-linking polymers, except, MMP-2 and HSP60 use the innate proteins without denaturing, plus zinc chloride ions was not applied in the solution, because in the MMP-2 molecule plenty zinc ions chelated with receptors, to study the system DET current flow pattern for with and without the presence of multiple biomarkers, such as glucose and pyruvate influences in different concentrations, to understand the PPI pattern in a quantitative and contour map method under the assumption of HSP60 will form a tall cylinder 3D nanostructure on top of the toroidal membrane structure of MMP-2. If possible, we would like to see the system having either, superconductivity or memristive, or none, or lucky to possess both characteristics. Therefore, this system capable of sensing clinically useful glucose concentration range and pyruvate becomes possible.

### SUMMARY OF INVENTION

It is an object of the present invention to evaluate the immunological advantage of human milk vs. organic cow milk regarding the pHFO formation at LPS challenges.

The intention is that the memcapacitor/memristor device is a sensor that represents, in concept, a baby's single neuron which is able to “feel” and react to the energy gain or loss in the presence of LPS. Our focus will be to determine how the pHFO occurs with dosage changes of LPS and the frequency change from SWS to 200 Hz.

It is an object of the present invention to demonstrate the memristor/memcapacitor's immunological capability in a contour mapping, that is based on a dual quantitative measurement of LPS in amperometric/voltage method while showing the advantage of human milk over cow milk.

It is an object of the present invention to provide a new generation of organic memristor/memcapacitor with Biomimetic FGFR-1 function and in Biomimetic of CHAT function in direct electron-relay systems.

It is an object of the present invention to provide a new generation of organic memristor/memcapacitor that is capable for dual sensing of functioning of AcCoA and LPS in single cell using milk specimen in current and voltage change without using antibody, mediator, labels and tracers.

### Summary of Current CIP Invention

It is an object of the present invention to provide a new generation of Josephson junction-based toroidal array superconductive/mem-element devices comprising multiple-layer superlattices made by self-assembling cross-linked native organometallic proteins that facility Cooper pair electrons hopping through the superlattices causing the Friedel-oscillation that paves a road for room temperature quantum superconducting and memristive capability.

It is an object of the present invention to provide a new generation of Josephson toroidal vortex array devices having arrays of 3D nano-cage structure with transition metal in d_{π} chelating bearing multiple functioning chemical and biological active receptors.

It is an object of the present invention to provide a new generation of Josephson toroidal array device facilitating Direct Electron Transfer (DET) forming long range electron-relay between the innate matrix metalloproteinase (MMP-2) and the innate Heat Shock Protein (HSP60) cross-linked multiple-layer polymer membrane, that the changing phases of the Cooper pair waves may be beneficial for direct multiple-biomarker sensing without use antibody or labeling.

It is an object of the present invention to provide a new generation of Josephson toroidal vortex array device not only superconducting, but also state watchable to memristive state by developing a new type of molecular “Valve”, in particular, a biomarker associated with a topological resistance “platform”, which serves as the molecular “Valve” that turns the superconducting state and the Mem-element state “On” or “Off” in a controllable manner, in other words, the molecular “Valve” participates the long-range electron-transfer relay in promoting state change in the 3D cage, wherein the Cooper-pairs in a 3D pathway from horizontal to perpendicular related to the membrane surface can be monitored without using any optical or electrical chopper.

It is an object of the present invention to provide a new generation of Fractional Josephson toroidal vortex array superconductive/mem-element device quantitatively direct senses and detects multiple-biomarkers in a biological medium.

It is a further object of the present invention to provide a new generation of Josephson toroidal vortex array superconductive/memristive device having a 3D-cage “Tesla Tower-like” multiple-layer nanostructured membrane possessed strong and unique Friedel-oscillation, that promotes Cooper-pairs hoping on the superlattice surface horizontally and jump-up vertically based on both of the receptor electron-transfer relay and the nanostructure guidance.

It is a further object of the present invention to provide a new generation of flexible Josephson toroidal vortex array superconductive/Mem-element power device, that is capable of self-producing terminal energy by using approaches of mimicking of the Glucose . . . Pyruvate . . . ACoA relay, or Glucose . . . Choline . . . ACoA relay, through obtain the catalysis embedded with many enzymes to mimic a single mitochondria power machine biological cell.

### BRIEF DESCRIPTION OF THE DRAWINGS

FIG. 1 illustrates an art model for the 3D toroidal memcapacitor.

FIG. 2A depicts the 3D AFM image of the nanostructured islands membrane on a 50 nm gold chip of TCD/PEG/PVP and β-CD copolymer without o-NPA. FIG. 2B depicts the 2D AFM of the nanostructured islands membrane on a 50 nm gold chip of above membrane.

FIG. 3A depicts the art model of the SAM molecular polymer architecture for mimicking FGFR-1 in the presence of o-NPA. FIG. 3B depicts the art model of the SAM molecular polymer architecture for mimicking active sits of CHAT.

FIG. 4A illustrates the frequency affect on the hysteresis of the i-V curves of the FGFR-1 sensor in pH 7.0 PBS over scan rate from 1 Hz to 1 KHz without LPS. FIG. 4B depicts the CV profiles organic milk controls.

FIG. 4C depicts the CV profiles of human milk controls, and FIG. 4D depicts the CV profiles in 500 ng/mL LPS in human milk. In FIG. 4D, at 20 Hz, “a” curve depicts the milk sample spiked with a final concentration 50 ng/mL LPS in red; “b” curve depicts the control human milk sample; “c” curve depicts 500 ng/mL LPS spiked in the human milk sample in black.

FIG. 4E depicts the CV profiles in 500 ng/mL LPS in organic milk on the hysteresis of the i-V curves over 1 to 300 Hz. At 20 Hz, “a” curve depicts the milk sample spiked with a final concentration 500.0 ng/mL LPS in black; “b” curve depicts 50.0 ng/mL LPS spiked in the organic milk sample in red.

FIG. 5A depicts the CA curve profiles in organic milk samples with spiked LPS covered concentration from “a” to “h” with LPS at 0.0, 5.0 pg/mL, 50.0 pg/mL, 5.0 ng/mL, 50.0 ng/mL, 125.0 ng/mL, 250.0 ng/mL and 500 ng/mL. Each sample run triplicates.

FIG. 5B illustrates the CA profiles in organic milk samples with spiked LPS covered concentration from “a” to “e” with LPS at 0.0, 5.0 pg/mL, 50.0 pg/mL, 500.0 pg/mL, 50.0 ng/mL clearly showing at lower concentration range of LPS, the peak intensity is distinguishable between samples with LPS and the control. Each sample run triplicates.

FIG. 6 depicts the calibration plot curve of current density vs. LPS concentrations in organic milks samples using the CA method.

FIG. 7A depicts two different media solutions affecting on the single neuronal pulses profiles at 0.25 Hz; FIG. 7B depicts the voltage profiles in 40 Hz and FIG. 7C depicts the profiles in 250 Hz between pH 7.0 PBS buffer (red curve) and the human milk without LPS (black curve), respectively at ±10 nA, each sample run triplicates. FIG. 7D depicts the DSCPO profiles with or without LPS over LPS concentration ranges at 0.0 (a), 50 (b), 100 (c), 500 (d) and 1000 ng/mL(e) at 0.25 Hz at ±10 nA with each sample run triplicates. Insert is the curves for LPS at 500 and 1000 ng/mL, respectively. FIG. 7E depicts the DSCPO profiles with or without LPS over LPS concentration ranges at 50 ng/mL (a), 500 ng/mL (b), 1,000 ng/mL (c) and 0.0 ng/mL as the control (d) at 200 Hz, respectively, each sample run triplicates.

FIG. 8A depicts the quantitative calibration plot of LPS in human milk at 0.25 Hz and FIG. 8B depicts the plot at 200 Hz compared with LPS in organic milk at 0.25 Hz (FIG. 8C) and 200 Hz in FIG. 8D.

FIG. 9A compares the LPS effects on organic cow milk over 0, 50, 500 to 1000 ng/mL at 0.25 Hz and FIG. 9B depicts the voltage curves of organic mil at 200 Hz, respectively.

FIG. 10A and FIG. 10B depict the energy density (as Z) contour map and the image, respectively, are shown using human milk. The LPS concentration (as X) and synapse frequency (as Y).

FIG. 10C and FIG. 10D depict the energy density (as Z) contour map and the image, respectively, are shown using organic milk in the presence of the LPS concentration (as X) and synapse frequency (as Y).

FIG. 11A depicts the 3D energy distribution map vs. frequency and LPS concentrations in human milk. FIG. 11B depicts the 3D energy distribution map vs. frequency and LPS concentrations in organic milk.

FIG. 12 depicts the CV profiles in human milk with and w/o AcCoA.

FIG. 13 illustrates the CV curves in organic milk with and w/o AcCoA.

FIG. 14 illustrates the CA curve profiles in PBS pH 7.0 in the presence of 2 mM o-NPA.

FIG. 15 shows the calibration plot of current vs. AcCoA concentrations.

FIG. 16 depicts the extended plot of current vs. AcCoA concentrations from 2.0 pM up to 0.3 μM.

FIG. 17A depicts the voltage profiles of detections of spiked AcCoA in human milk compared with control at 0.25 Hz. FIG. 17B depicts the voltage profiles at 250 Hz.

FIG. 18A depicts voltage profiles of detections of spiked AcCoA in organic milk compared with control at 0.25 Hz. FIG. 18B depicts the voltage profiles of detections of spiked AcCoA in organic milk at 250 Hz.

### Following are the Brief Descriptions of the Drawings for the CIP Application

FIG. 19A depicts the 3D AFM image of the MMP-2 membrane as the first layer in 1.0 μM². FIG. 19B depicts the 2D AFM image in a larger area of 8.9×8.9 μm². The multiple toroidal shaped structures with diameters varied from 1.8 μm to 4.8 μm and the toroidal thickness varied between 50-90 nm. FIG. 20A depicts the second layer of tower structure HSP60 AFM image multiple-enzyme network membrane (30×30 μm²) which is on top of the first layer of MMP-2.

FIG. 20B depicts the toroidal “diamond ring” structure in detail, FIG. 20C depicts the 907.9 nm×907.9 nm area and a diameter 300-360 nm toroidal ring in detail; FIG. 20D depicts the donut-shape toroidal qubit and FIG. 20E depicts another AFM image from a different area for the tower glow with Cooper-pair moving compared with the background superlattice of toroidal rings. FIG. 20F depicts the 3D AFM image of the nanometer size “Tesla Tower).

FIG. 21A depicts the HSP60/MMP-2 model used for elucidating the proposed protein MMP-2 . . . HSP60 PPI in the form of DET chain in the toroidal . . . cylinder membrane through a GA medium insulator platform. “1”: the electrode; “2”: MMP-2 cross-linked membrane serves as a zinc finger Cys₁His₃; “3” HSP60 dimer cross-linked membrane; “4”:PEG . . . PVP . . . TCD cross-linked cap. FIG. 21B depicts the symbol of the flexible Josephson toroidal vortex junction. The center “8” shape hummingbird is a symbolic representation of the circular electron-relay system. FIG. 21C depicts the FTVJJ circuit configuration.

FIG. 22A depicts the i-V curves under different scan rate from 20 Hz to 25 kHz for the HSP/MMP device in pH 7.0, 10 mM PBS buffer solutions. FIG. 22B depicts the i-V curves under the impact of 60 μg/dL glucose concentration in the PBS buffer under the same condition, and using the same sensor. FIG. 22C depicts the i-V curves under the impact of the 3 nM ACoA concentration in the PBS buffer over scan rate 1 Hz to 20 kHz; FIG. 22D depicts i-V curves under the impact of 10 μM choline concentration in the PBS buffer over the scan arte from 60 Hz to 25 kHz. Some the curves are with 10 consecutive 10 cycles. FIG. 22E depicts the i-V curves under the impact of 5 fM pyruvate concentration in the PBS buffer over the scan rate from 20 Hz to 25 kHz. FIG. 22F depicts the i-V curves of the GA medium which comprises of 3 nM ACoA and 1 mg/dL glucose in the pH 7.0, 10 mM PBS solution under the impact of scan rate change from 60 Hz to 25 kHz, among them 10 consecutive cycles are shown in 60 Hz and 20 kHz. Glucose concentration change impacts on the GA medium's i-V curves were also displayed in two scan rates, 60 Hz and 20 kHz, respectively, glucose concentration changes from 1 mg/dL, 80 mg/dL to 300 mg/dL, while kept the ACoA concentration constant as 3 nM, with 10 consecutive scan cycles, respectively was shown.

FIG. 23 Panel A depicts the quantum conductance of the HSP60/MMP-2 device in PBS buffer vs. potential at 60 Hz, FIG. 23 Panel B depicts the curve at 2 kHz, FIG. 23 Panel C is for 20 kHz and FIG. 23 Panel D is for 25 kHz, respectively.

FIG. 24 depicts the plot of Josephson frequency vs. Shapiro step voltage over scan rate 60 Hz to 25 kHz.

FIG. 25A depicts the device responses to various glucose concentrations from hypoglycemia to hyperglycemia 10 mg/dL to 1000 mg/dL in the i-V curves at a scan rate 60 Hz compared with the control. FIG. 25B depicts the contour map between the MEM peak current, DET peak location and the glucose concentrations based on data shown in FIG. 25A. FIG. 25C depicts the calibration curve of Memristive current vs. glucose concentration. The insert is the calibration of the DETₒₓ current vs. glucose concentration in the PBS buffer.

FIG. 26 Panel A depicts i-V curve “a” in glucose 1 mg/dL and ACoA 3 nM, the (GA) medium as the control compared with the i-V curves “b” with 3 nM ACoA only control for consecutive 10 scan cycles in the PBS buffer from of the Device. FIG. 26 Panel B shows the i-V curve in the presence of 80 mg/dL glucose in the PBS buffer only for the comparison. FIG. 26 Panel C depicts the i-V curve in the 80 mg/dL glucose concentration with ACoA 3 nM for 10 scan cycles. FIG. 26 Panel D shows the memristive i-V curve of 5 fM pyruvate analyte in the PBS buffer. FIG. 26 Panel A, B, C and D are at 60 Hz scan rate. FIG. 26 Panel E depicts the i-V curve “a” with the GA medium only at scan rate 1 kHz compared with the i-V curve “b” in the presence of 10 pM pyruvate with the GA medium under the same 1 kHz scan rate.

FIG. 27 Panel A depicts the i-V curve “b” in the presence of 5 fM pyruvates in the GA medium compared with the i-V curve “a” of the GA medium control. FIG. 27 Panel B depicts the i-V curves “b” and “c” with 50 fM and 10 pM pyruvate in the GA medium compared with the GA media control i-V curve “a”, which comprised of 3 nM ACoA and 1 mg/dL glucose solutions in pH 7.0 PBS at 60 Hz scan rate. FIG. 27C depicts the fractional Josephson junction's relative signal vs. phase Φ at 4 π in the presence of 5 fM pyruvate in the GA media at Josephson frequency 469 GHz compared with the GA media control. FIG. 27D depicts the calibration curve of the absolute value of the DETₒₓ peak current vs. pyruvate concentrations over 5 fM to 0.1 nM in the GA media with scan rate 60 Hz. The insert is the calibration curve of the DET_{red} peak current vs. pyruvate concentrations in a semi log plot.

FIG. 28 Panel A depicts the control's i-V curve “a” in the GA medium of 3 nM ACoA and 1 mg/dL glucose at 1 kHz scan rate. The i-V curve “b” depicts in the presence of 10 pM pyruvate in the GA medium at 1 kHz. FIG. 28 Panel B depicts the i-V curves “b” with 10 pM pyruvate in the GA medium at 2 kHz compared with the GA control. FIG. 28 Panel C depicts the i-V curve “b” at 20 kHz with 10 pM pyruvate in the GA medium compared with control GA medium curve “a”. FIG. 28 Panel D depicts the i-V curve “b” is with 10 pM puruvate in the GA medium at 25 kHz compared with the GA medium control i-V curve “a”.

FIG. 29A depicts the quantum conductance 3d map in 2 kHz scan rate in the PBS buffer. FIG. 29B depicts the quantum conductance map for the HSP60/MMP-2 device in the presence of 10 pM pyruvate in the GA media having 1 mg/dL glucose and 3 nM ACoA in the PBS solution at the same scan rate. FIG. 29C depicts the superposition states at zero-bias in the presence 10 pM pyruvate in the Josephson frequency 153 GHz “a” vs. “b” at 97 GHz. FIG. 29D depicts the plot of quantum conductance vs. potential in the presence of 10 pM pyruvate in the Josephson frequency 153 GHz curve “a” vs. 97 GHz, curve “b”.

FIG. 30 depicts the contour map of the DETₒₓ current from glucose and pyruvate contributions to the quantum conductance.

FIG. 31 depicts the curves of current vs. time with or without pyruvate over 5 fM to 1 μM compared with the GA medium control. Each sample run triplicates.

FIG. 32 depicts the semi-log plot of the calibration curve.

FIG. 33 depicts the curves of the open circuit potential change vs. time under the impact of 10 pM pyruvate concentration, 10 μM choline with or without the presence of GA medium (glucose 1 mg/dL and ACoA 3 nM in the PBS buffer), compared with different controls of the biomarkers in the PBS buffer.

. FIG. 34 depicts the time course impacts on the curves of the open circuit potential vs. time in 30 s, 120 s, 960 s and 1800 s, respectively in the PBS buffer using the innate HSP60/MMP-2 sensor. The insert is the curve for 1800 s with the first-order curve fitting results shown in the insert.

Table 1 summarized the results obtained using the open circuit potential method for comparison of the terminal energy, pseudo-first order rate constant, r value and the fitting Chi^{\hat{ }2}/Dof results for with or without using the GA medium in the presence of different biomarkers.

### DETAILED DESCRIPTION OF THE INVENTION

### Example 1

### Fabrication of the Nanostructure Self-Assembling Membrane (SAM) Gold Memristive/Memcapacitive Chips

The nanostructured biomimetic SAM was freshly prepared according to the published procedures based on cross linked conductive polymers of triacetyl-B-cyclodextrin (TCD), polyethylene glycol diglycidyl ether (PEG), poly(4-vinylpyridine) (PVP) and B-CD copolymer with appropriate amount of propositions on gold chip [21-22]. The chemicals were purchased from Sigma and went through purification procedures before use. A mixture of o-nitrophenyl acetate (o-NPA) in a molar ratio 1000:1 to the TCD mixture was incubated for 2 hrs at 35° C.; then the mixture was injected onto the gold surface and incubated for 48 hrs at 35° C. After that, we followed the clean procedures for completion of the SAM fabrication [21-22].

### Example 2

### Characterization of the Membrane

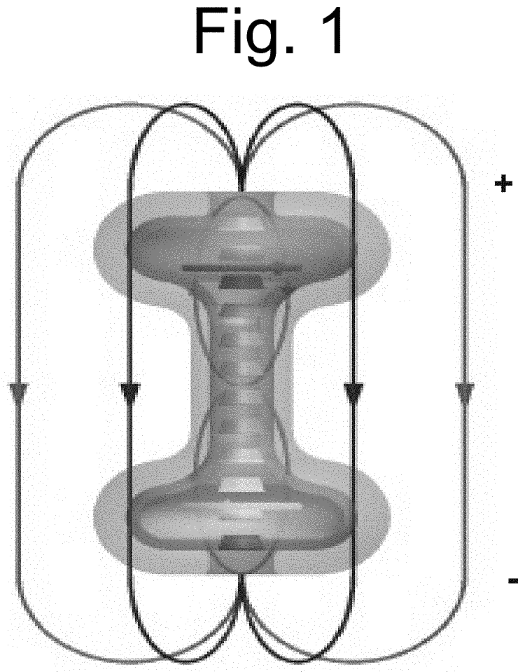

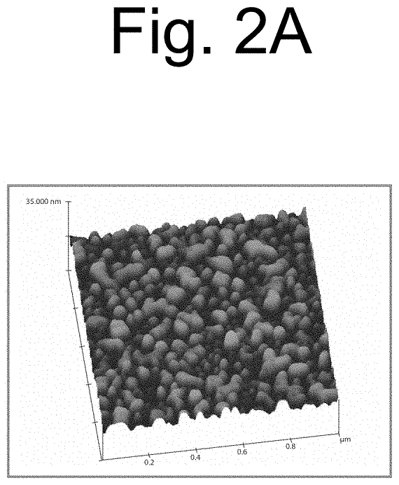

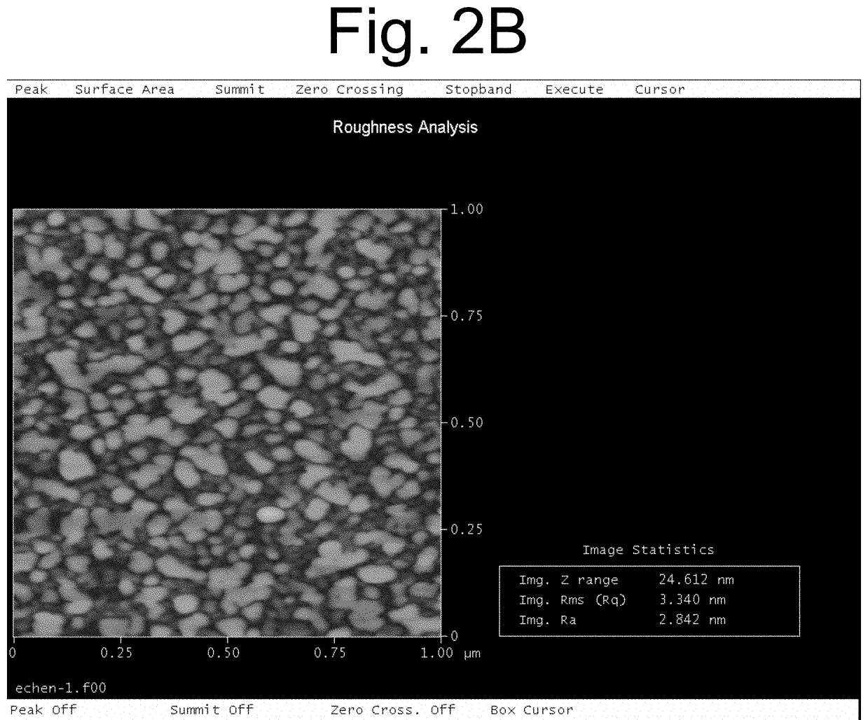

The morphology of the AU/SAM was characterized using an Atomic Force icroscope (AFM) (model Multimode 8 ScanAsyst, Bruker, Pa.). Data Collected in PeakForce Tapping Mode. Probes used were ScanAsyst-air probes (Bruker, Pa.). The silicon tips on silicon nitride cantilevers have 2-5 nm radius. The nominal spring constant 0.4N/m was used. FIG. 1 illustrates an art model for the 3D toroidal memcapacitor. FIG. 2A depicts the 3D AFM image of horizontal conformational structure of the memristor/memcapacitor before the o-NPA was embedded on gold. FIG. 2B shows the 2D AFM image.

### Example 3

### Advantage of AcCoA's Rate Limiting Binding

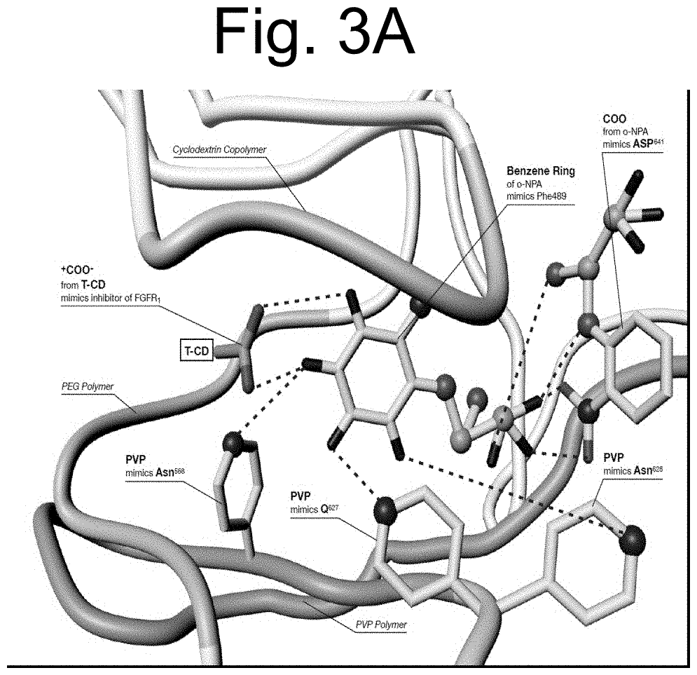

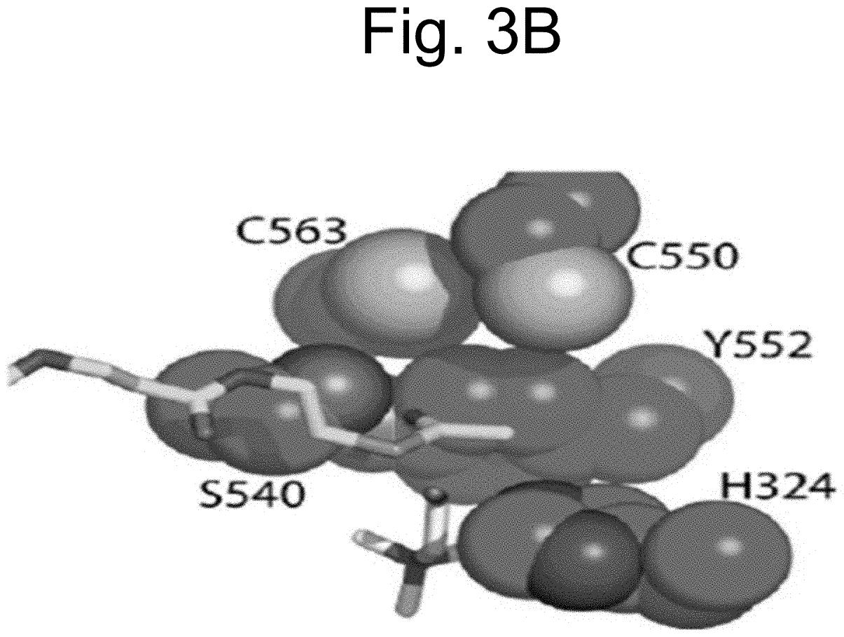

Using the nano island structure SAM to mimic the function of Fibroblast Growth Factors Receptor-1 (FGFR-1) for improving fuel cell function was reported as shown in FIG. 3A [E. Chen's patent 8,632,925, Jan. 21, 2014]. It plays important roles in embryonic development, angiogenesis, wound healing, and malignant transformation (11). We thought using the function groups in the SAM membrane to mimic the AcCoA's human choline acetyletransferase (CHAT) binding sites intrinsically to mitochondria's double membrane compartment with the structure needed may be a simplified approach as a neuronal sensor model. The model of the device is to mimic CHAT's function in emphasizing of AcCoA's rate limiting step binding [1-5]. The possible electron-relay was proposed by the pyridine group in PVP, the COO⁻ group of TCD, the OH group from β-CD copolymer, and the carbonyl group from o-NPA through hydrogen bindings to be able to mimic s540, y552, c563, c550 and h324 of AcCoA binding sits in CHAT as Shown in FIG. 3B. The innovative approach is to first direct detect AcCoA in the mimicking binding sites of CHAT, without choline participates in the direct detection of AcCoA.

### Example 4

### Biomimetic Fibroblast Growth Factor Receptor 1 (FGFR1) SAM membrane

FGFR1 is one of family receptors of tyrosine kinases. It plays important roles in embryonic development, angiogenesis, wound healing, and malignant transformation, bone development, and metabolism [35-36]. Y. Zhang's group reported mice with deleted FGFR1 exhibited an increased mobilization of endothelial progenitor cells (EPCs) into peripheral blood undergoing endotoximia, and the endotoximia was induced by injection of LPS [36]. Our project's initial step is to build a model device such that the device's SAM membrane mimics the FGFR1 receptor in the presence of LPS, which acts as a model metabolic product to access the FGFR1 function. By using this model to compare the effects of fresh human milk and organic cow milk at different frequencies of neuronal action/resting pulses at SWS and fast gamma frequency with or without LPS conditions to find out whether or not milk samples are energy efficiency or deficiency on the biomimetic brain cells will provide useful information to reveal which type of milk samples is immunologically advantage to infants. FIG. 3A shows the electron-relay system, and FIG. 2A and 2B are the AFM images in 3D and 2D on a gold chip with the TCD/PEG/PVP/copolymer before adding o-NPA for embedding.

### Example 5

### Frequency Affects on Memristor/Memcapacitor's Performance

Evaluations of frequency's affect on memristor performance were conducted by Cyclic Voltammetric method (CV) in pH 7.0 saline solution at room temperature from a scan rate of 1 Hz to 1 KHz without using any biological specimen. Data are to be used for comparison between fresh human milk and USDA certified organic milk for infants with or without the presence of LPS covering the same range of real-time synapse action/resting potential pulses at different frequencies against controls.

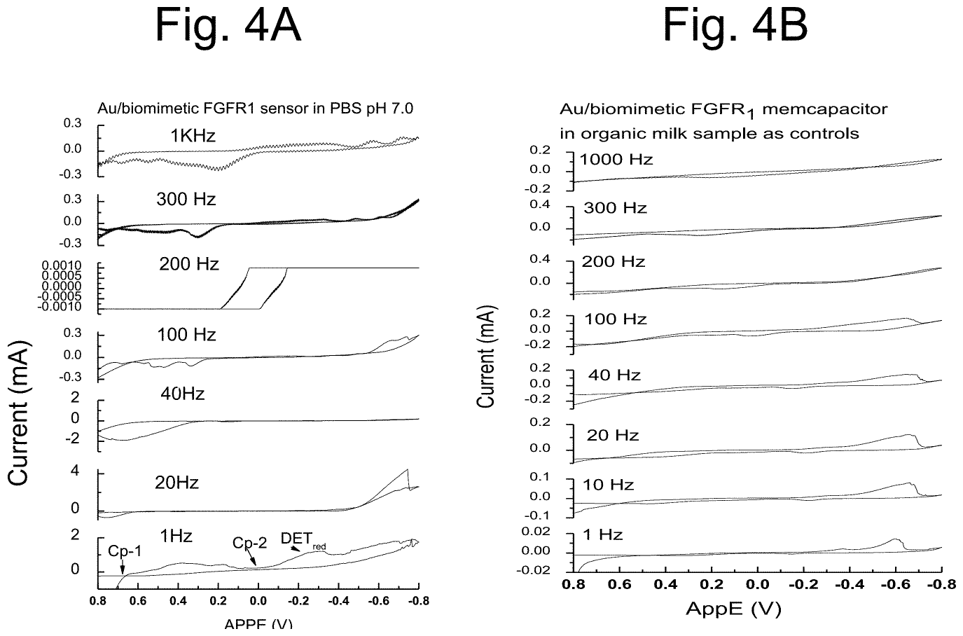

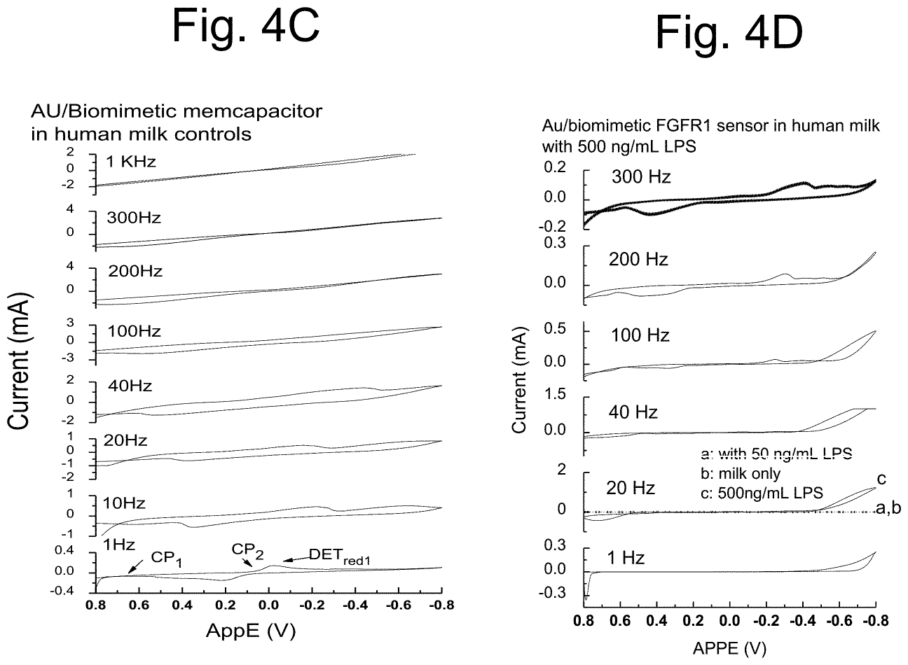

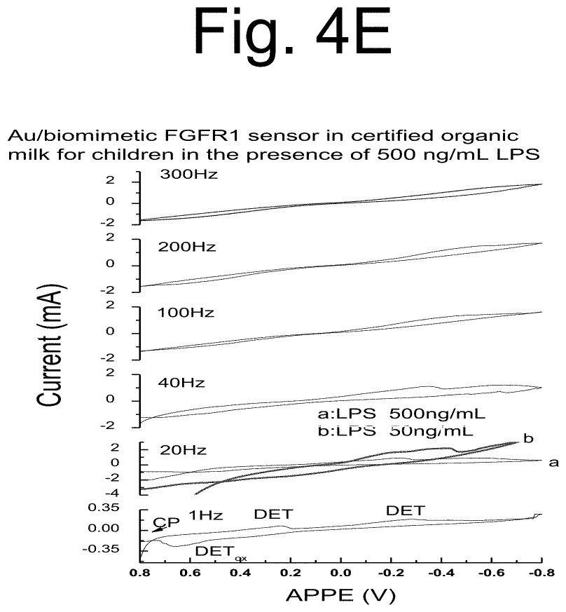

FIG. 4A's i-V hysteresis curves were demonstrated with a switch point at the origin (0, 0) at almost all frequencies, except at kHz high frequency in the control medium PBS. When these perfect hysteresis behavior peaks occurred, especially at SWS frequency with a sensitive Direct Electron-Transfer (DET), and the switch point originates at origin, it indicates a healthy “newborn single neuron” exists before “feeding” it milk samples. Nonlinear frequency influence on current intensity is a characteristic of the memristor as reported in literature [9-12, 37-40]. FIG. 4B shows the controls in organic milk samples over 1 Hz to 1 kHz. The significant difference observed between the organic milk control, the PBS control, and the human milk control at SWS is that the organic milk did not have a butterfly type DET_{red} peak near −0.1 to −0.2 V, where as PBS and human milk had this peak and cross-points near the origin. Rather, the organic milk control had a strange DETred peak at −0.595 V, and the control missed the cross-point near zero V. Further investigation is needed to determine what substances caused the unknown DET peak to occur. FIG. 4C is the human milk controls with well-defined sensory DET butterfly peaks crossed near the origin at SWS. FIG. 4D depicts that in human milk, 500 ng/mL LPS reduced the signal intensity at the SWS significantly. The LPS eliminated the original sensitive DET peaks, and that means the LPS first makes the neuron lose its sense of danger in the presence of toxins; this phenomenon matched our prior observations in the work of β-amyloidal (Aβ) that caused Alzheimer's sensory loss at SWS [9-12, 30, LPS, PSI]. In the worst case, the cow milk with LPS impaired heavily the DET sensory ability of our model neuron as compared to that in human milk, as shown in FIG. 4E.

### Example 6

### Quantitation of LPS Using the CA Method

Quantitation of LPS was conducted with two methods. The first was a Chronoamperometric (CA) method under two steps of fixed potential: −50 mV and −400 mV with each step duration of 100 ms, and the data rate is 20 kHz at room temperature under the conditions of antibody-free, radioactive tracer-free and reagent-free in certified organic milk for infants with seven LPS challenge levels from 5.0 pg/mL to 500 ng/mL against controls, each sample run triplicates.

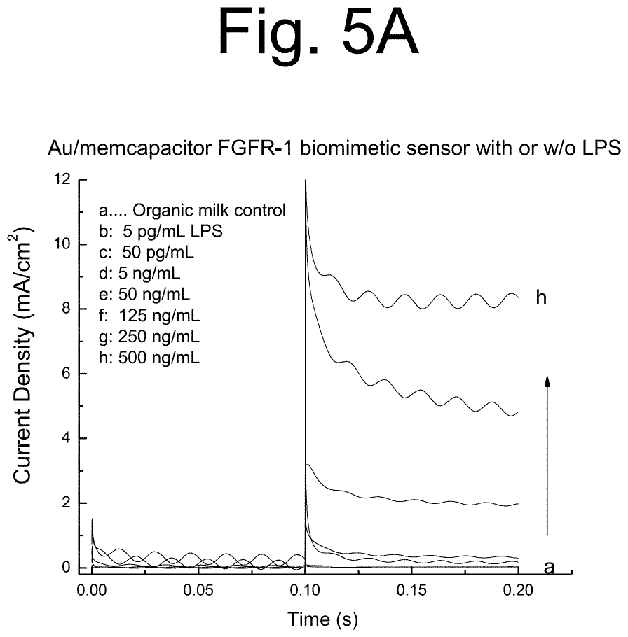

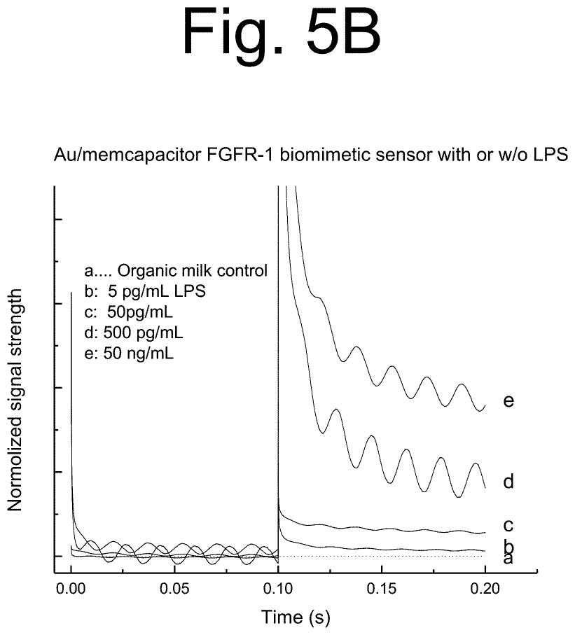

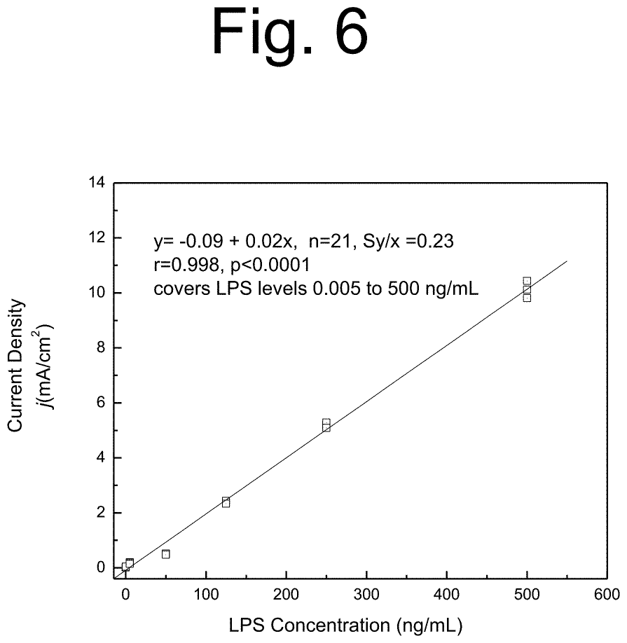

The CA Method. The CA curve profiles were plotted using the biomimetic sensor in the presence of seven LPS concentration levels from 0, 5.0 pg/mL, 50.0 pg/mL, 5.0 ng/mL, 50 ng/mL, 125 ng/mL, and 250 ng/mL to 500 ng/mL against the control in organic milk samples as shown in FIG. 5A. FIG. 5B depicts the lower level LPS's response curves, showing more clearly the significant increase in signals at 5 pg/mL LPS over the control. The CA method for LPS produced a calibration curve with the regression equation y=−0.09 +0.02x, n=21, S_{y/x}=0.23, r=0.998 with p<0.0001 covering the linear range from 5 pg/mL to 500 ng/mL in organic milk samples as shown in FIG. 6. The DOL result is 0.1 pg/mL per one cm² sensor in organic milk, i.e., by the CA method we are able to detect 5.0×10⁻⁴ EU E. Coli in 1 mL sample in 1 cm² sensor. Using this 0.031 cm² sensor, we are able to detect E. Coli cells in the range of 0.2-5 cell assuming 5EU contains 2000-50000 E. Coli cells' activity [13, LPS, PSI]. The percentage of Pooled Relative Standard Deviation (PRSD %) of the organic milk samples over the entire linear range is 2.0%.

### Example 7

### Quantitation of LPS Using the Voltage Method

The second quantitation method was the voltage method, i.e., the DSCPO method, and the conditions were the same as described in the section of Assessing Energy Outcomes under Challenges of LPS by using human milk and organic cow milk samples under 4-5 LPS challenges from 50 ng/mL to 1000 ng/mL, respectively at ±10 A against controls at 0.25 and 200 Hz, respectively. Freshly obtained samples were without pretreatment. Human milk cooled by dry ice was delivered to the laboratory, and it was brought to room temperature naturally without any heating before spiking the LPS. All water used was autoclaved and double distillated from Fisher Scientific. LPS was purchased from Sigma, and it was dissolved in autoclaved and filtered PBS pH 7.0 buffers.

The Double Step Chronopotentiometry (DSCPO) method, as the voltage method, was used for assessing energy outcomes of slow-wave-sleeping (SWS) at 0.25 Hz and 200 Hz under the challenge of LPS at concentration ranges from 0, 50, 100, 500, to 1000 ng/mL of 4-5 levels with triplicates at ±10 nA, respectively. Samples were tested at each level without prior sample preparation, such as dilution or heating. The experiments were conducted at room temperature. The milk samples compared were human milk and USDA certified organic cow milk for infants, with and without LPS. Human milk was collected from a normal subject who breastfeeds a 1 month-old newborn (Lee Biosolutions Corp.). An electrochemical workstation was used (Epsilon, BASi, IN) with a software package from BASi. OriginPro 2016 (Origin Lab Corp., MA) was used for all statistical data analysis and figure plotting.

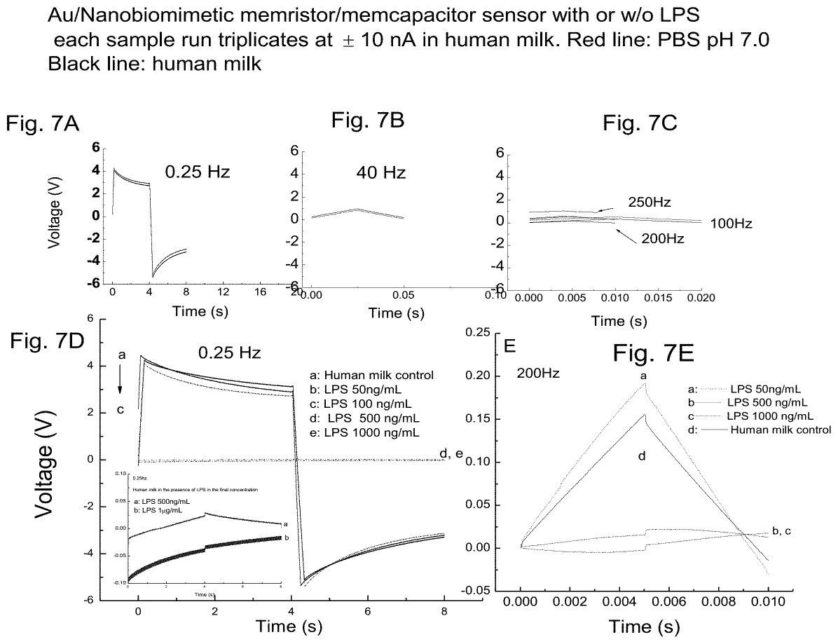

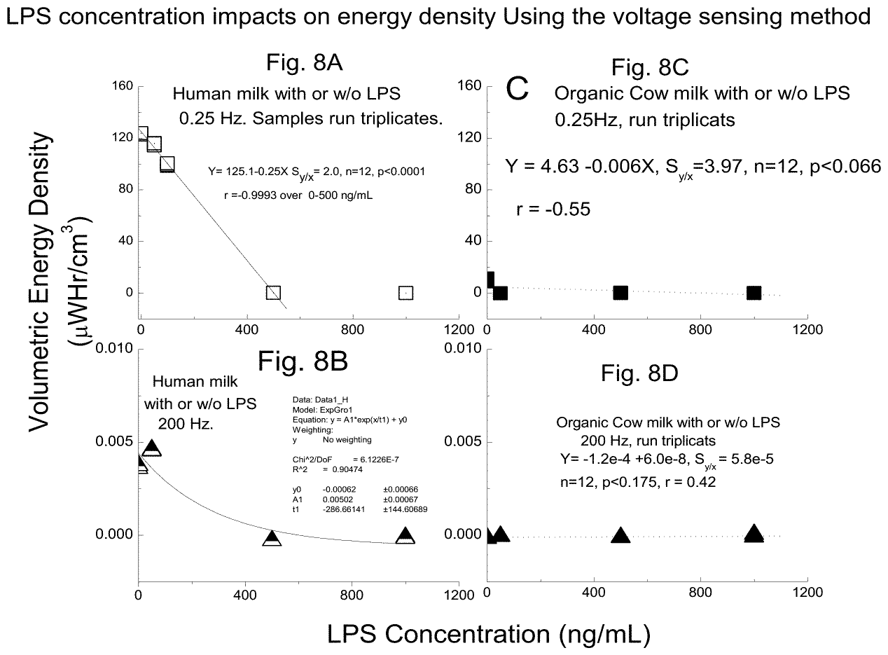

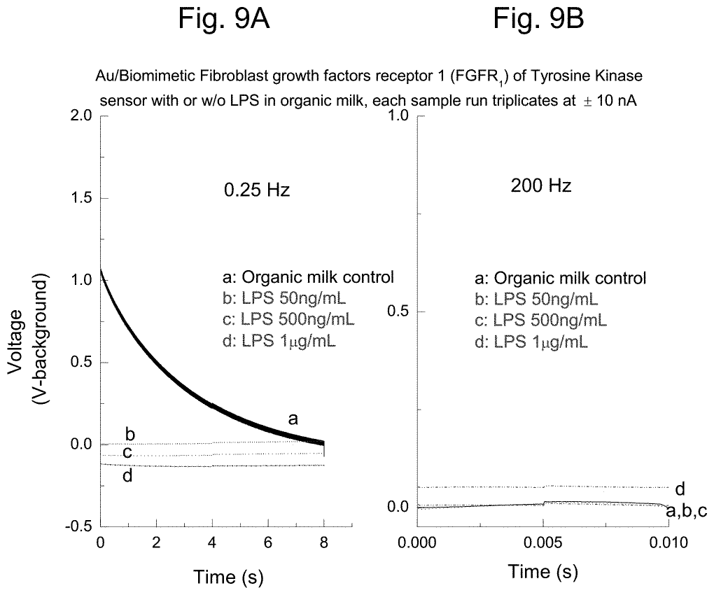

Assessing energy outcomes was conducted by comparing human milk and certified organic milk, both with and without LPS, at 0.25 Hz and 200 Hz, respectively, using the voltage method. FIG. 7A, 7B, 7C depict the synapse pulse control profiles using human milk, and compares samples using PBS media at 0.25, 40, 100, 200 and 250 Hz, respectively, without LPS. Curves overlap between the two media, and indicate human milk had no protein interference with the “single neuronal cell” as far as the neuron's energy output is concerned. FIG. 7D compares the signal intensity when testing human milk in the presence of various LPS concentrations at 0.25 Hz and the results show the signal intensity is inversely proportional to a wide range of LPS concentrations from 50 ng/mL to 1000 ng/mL at 0.25 Hz. At 50 to 100 ng/mL, the biphasic pulse shape integrity is maintained; however the insert curves show that at 500 and 1000 ng/mL, the biphasic pulses are destroyed, and the cell net voltage intensity is close to zero. FIG. 7E demonstrates a similar trend at 200 Hz, that the cell net voltage gets close to zero, at a higher concentration at 200 Hz, but at 50 ng/mL, the signal increases more than 30% compared with that at zero LPS. This is a bad effect, a negative outcome of wasted energy. FIG. 8A depicts the quantitative calibration plot of LPS in human milk at 0.25 Hz and FIG. 8B depicts the plot at 200 Hz compared with LPS in organic milk at 0.25 Hz (FIG. 8C) and 200 Hz in FIG. 8D. FIG. 9A compares the LPS effects on organic cow milk over 0, 50, 500 to 1000 ng/mL at 0.25 Hz and FIG. 9B depicts the voltage curves of organic mil at 200 Hz, respectively.

FIG. 8A illustrates the linear calibration curve at 0.25 Hz of volumetric energy density vs. LPS concentration range from 50 to 500 ng/mL using human milk, and it produced a linear regression equation Y=125−0.25X, r=0.9993 (n=12), P<0.0001, Sy/x=2.0. The Detection of Limits (DOL) is 0.3 ng/mL, i.e., in a 404, sample; it detects 12 pg LPS using a 1 cm³ sensor, our sensor is 3.11×10⁻⁷cm³. Herein the DOL in our sensor is 3.73×10⁻¹⁸g for LPS means we are able to detect a single E. Coli bacterium because an antigen is in 10⁻¹⁷g range. At 0.25 Hz, the energy density ranges between 123.2 and 0.11 μWHr/cm³ using human milk specimens with an imprecision value 3.0% compared the energy range of 9.8 to −0.042 μWHr/cm³ for organic milk. FIG. 8B shows the nonlinear curve for LPS at 200 Hz using human milk. In contrast, FIG. 8C and 8D show no sensitivity towards LPS over the same concentration range using organic milk. Human milk offers more than 12.5-fold high energy than organic milk and 100-fold sensitivity for LPS than organic milk.

### Example 8

### A Contour Mapping Method for Evaluation of Human Milk Immunological Advantage under the LPS Challenge

The data obtained from the quantitation using the voltage method was used for evaluation of human milk immunological advantage under LPS challenges compared with that of the organic cow milk samples in 3D mapping method. The energy density results were put into the “y” column, the spiked LPS concentration over 0.0 to 1000 ng/mL was put into the “x” column, and the frequency was at the “z” column having two levels of 0.25 to 200 Hz. After converting the three data columns into a random XYZ correlation matrix, one can plot the contour maps and analyze the spatiotemporal formation of the pHFO, if it exists among human milk or organic milk samples. The real-time data obtained from the DSCPO method was converted to volumetric energy density, E=Cₛ·(ΔV)²/(2×3600), where Cₛ is the specific volumetric capacitance, Cₛ=[−i·Δt/ΔV]/L, Cₛ is in F/cm³ [33-34], Δt is the time in second, ΔV is the voltage in V, i is the current in Amps, and L is the volume in cm³.

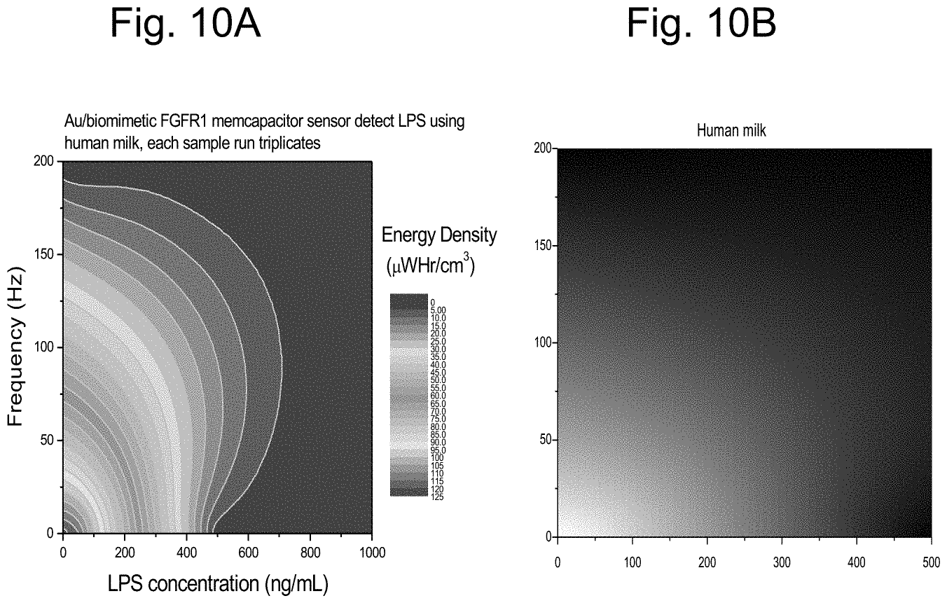

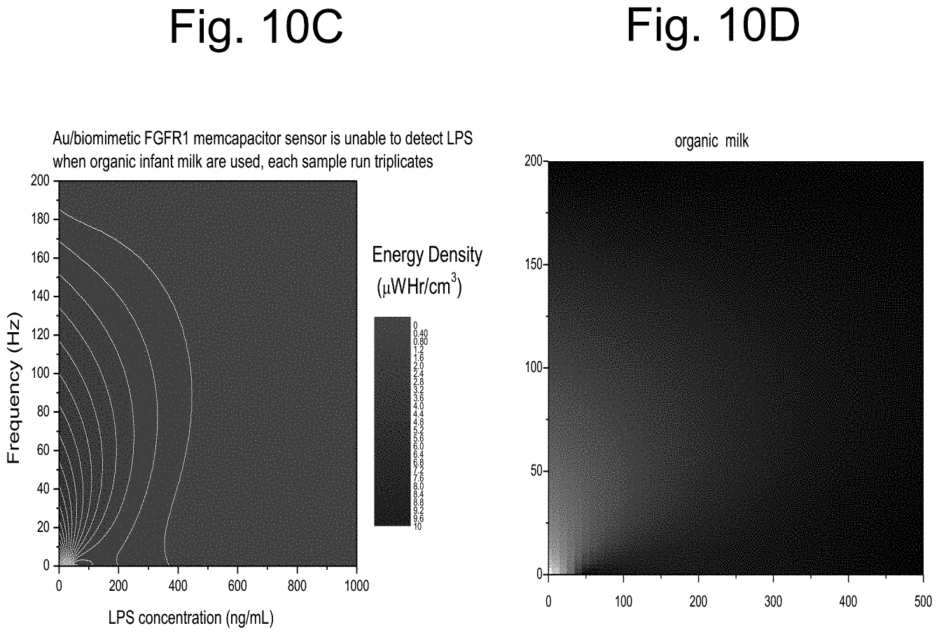

The energy density contour maps associated with the images are presented in FIG. 10 with energy density as Z, LPS concentration as X, and discharge pulse frequency as Y. FIGS. 10 A and 10B depict the contour map of energy density vs. LPS concentration in the frequency change using the human milk samples and FIG. 10C and 10D depict the contour map of energy density vs. LPS concentration in the frequency change using the organic milk samples. It is obvious that human milk produced tremendous higher energy (showing as the light in the image) with an intensity more than 10-fold higher, especially at SWS even in the presence of LPS.

### Example 9

### Evaluation of Immunological Advantage under LPS Challenges

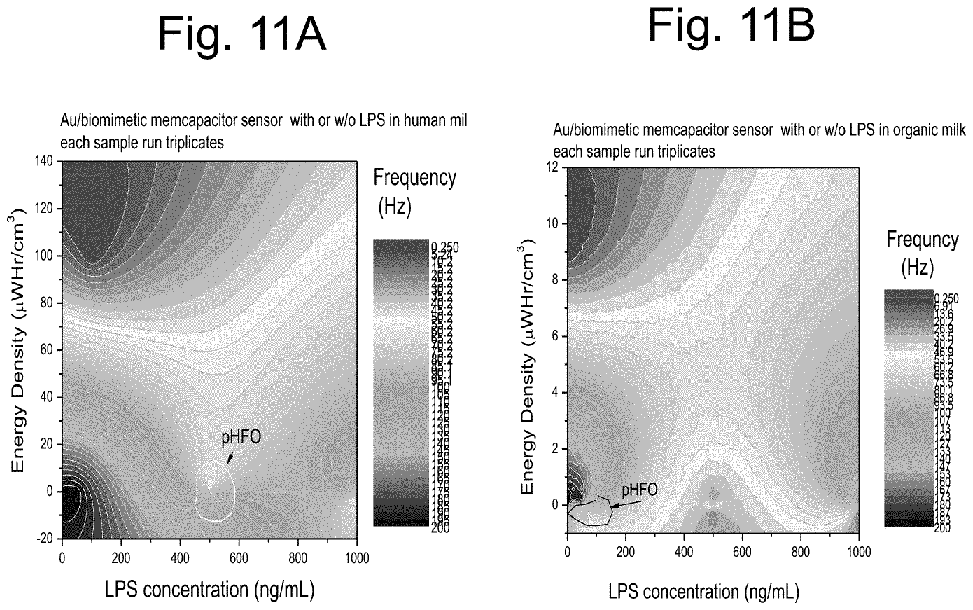

The comparisons of the immunological advantage under LPS challenges were evaluated through the study of the formation of the pHFO using a 3D energy density map method. The energy density results were put into the “y” column, the spiked LPS concentration over 0.0 to 1000 ng/mL put into the “x” column and the frequency was into “z” column having two levels of 0.25 to 200 Hz. After converting the three data columns into a random XYZ correlation matrix, one can plot the contour maps and analyze the spatiotemporal formation of the pHFO if a pHFO exists among human milk or organic milk samples. FIG. 11A depicts a 3D contour map of the relationship between energy density, LPS concentration and frequency using human milk. As we can see, at SWS, human milk held the highest neural synapse energy for with or without the presence of LPS challenge over the range from 0.0 ng/mL LPS to less than 200 ng/mL, until the LPS reaches 500 ng/mL, the energy gradually reduced to zero, in other words, human milk samples have an order of magnitude higher energy density at LPS=0 vs. organic milk at SWS and 200 Hz, respectively as shown in FIG. 11 A compared with FIG. 11B. At 0.25 Hz, 50 ng/mL LPS caused 100% energy reduce in organic milk vs. human milk only 6.25% reduced. The rate of LPS reducing synapse energy is 10-times faster in organic milk samples than in human milk samples. It is estimated from the map at LPS 5 EU/ng, human milk maintained 96.6% original energy strength vs. organic milk only 49% strength at 0.25 Hz.

### Example 10

### Assessing the Neuronal Network Sensory by DET and the Hysteresis Switch Point

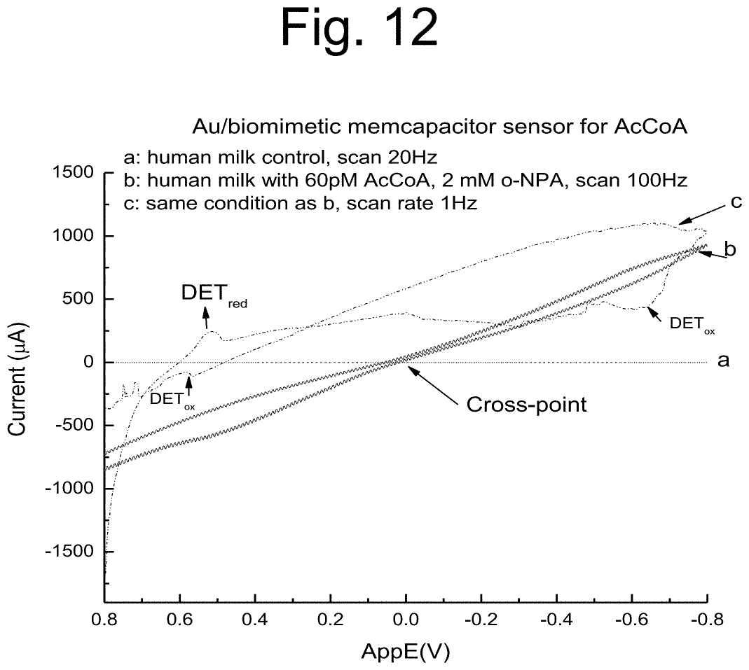

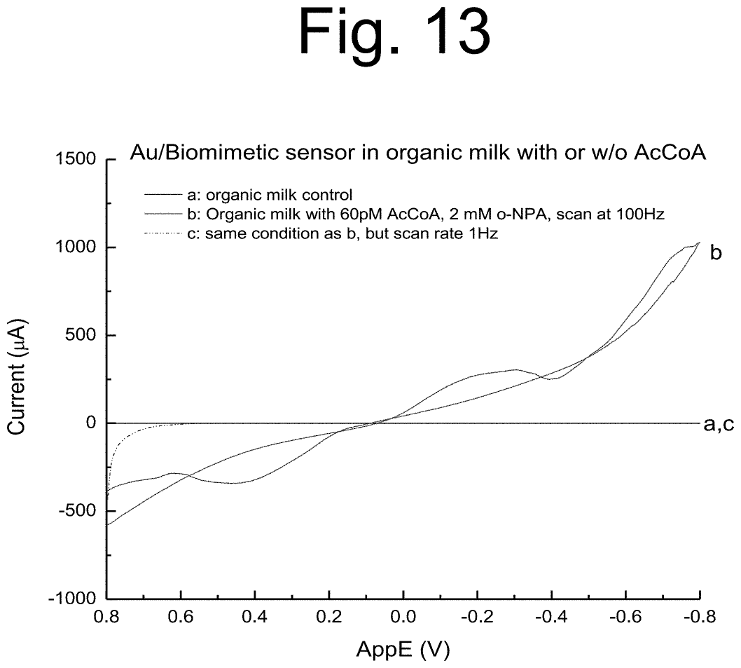

A “neuron” memristor's performance in i-V curves using fresh human milk or organic milk with or without 60 pM AcCoA as shown in FIG. 12 and FIG. 13. The sensor responded to human milk and organic cow milk differently. For example, at 1 Hz, the sensor has more DET peak and hysteresis switch points with human milk compared to organic milk, which has none, regardless of whether the samples are tested with or without AcCoA. These figures revealed human milk provides the single neuron a critical sensory function at the memory consolidation stage of brain development, and safe guards the reversible membrane potential in place, and ensures the normal function of direct electron-relay. The possible source or cause may be the contribution of the good bacteria as compared to the cow milk, which has none [www.en.wikipedia.org], because pasteurization of cow milk destroys both good and bad bacteria [www.en.wikipedia.org]. Another source which may contribute to the brain development may be the unique proteins such as A2 .beta.-casein, which is plentiful in human milk, and lacking in cow milk [S. Ho et al., European J. of Clinical Nutrition 68(9), 994-1000, 2014]. FIG. 13 shows there are no DET peak and no cross-point occurrence at 1 Hz with organic milk, and that indicates the cow milk offers a disadvantage for infant development compared with human milk. In contrast, at 100 Hz, the cross-points and DET peaks showed up in the i-V curve when spiked with AcCoA, and that may be the key reason causing energy drainage as evidenced in following sections. However, a dosage of AcCoA at 60 pM does do damage to the neuron even when using human milk, as evidenced by the moving away of the cross-point from the origin, and the energy was reduced as shown in the following section.

### Example 11

### Quantitation of AcCoA by the CA Method

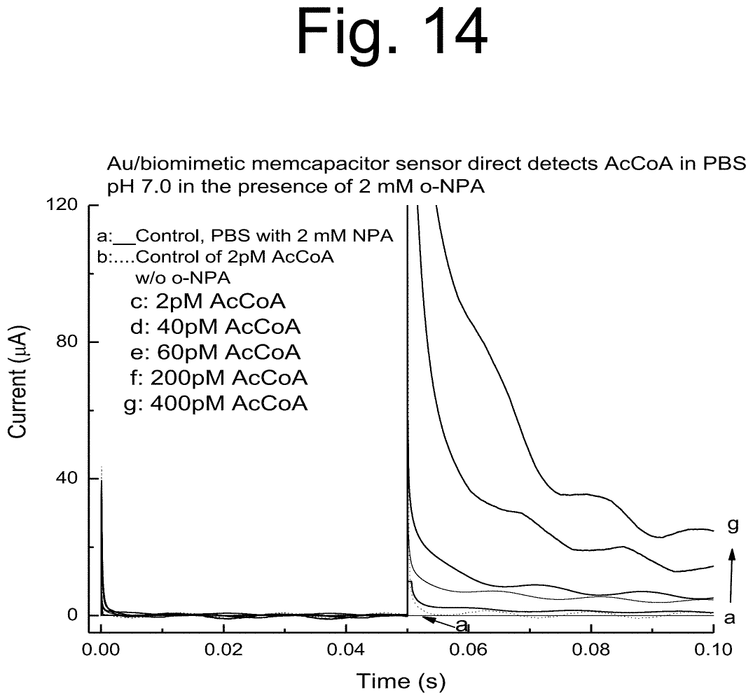

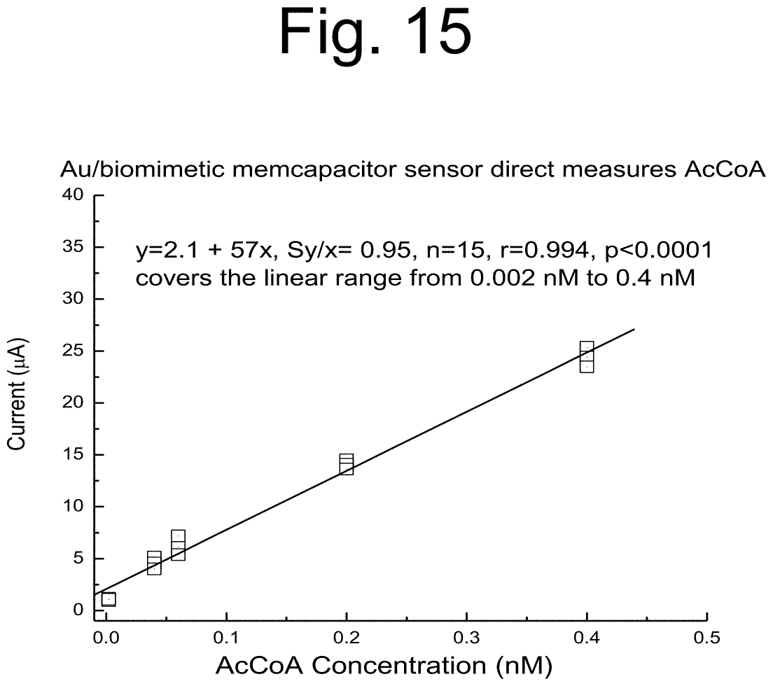

The CA method procedures are cited in paragraphs [00048]. The data were acquired at room temperature under two-step fixed potentials in 6 concentration levels covering AcCoA final concentrations ranging from 2.0.times.10.sup.-12M to 4.0.times.10.sup.-10M, with triplicates in pH 7.0 PBS in the presence of 2 mM o-NPA against 2 controls, one with 2 mM o-NPA, and another control without o-NPA. Accuracy was accessed by organic milk specimen samples with 60 pM spiked AcCoA, run triplicates; obtain the signal and then using the sample signal divided by the data obtained from the calibration curve to obtain the percentage of recovery. FIG. 14 illustrates CA curve profiles of AcCoA over the linear range of 2.0.times.10.sup.-12M to 4.0.times.10.sup.-10M in the presence of 2 mM o-NPA. The role of o-NPA is for enhancing of the hydrophobicity [16, 18-19], and it has no signal interference with AcCoA as shown in the control. The profiles show the signal intensity is in direct proportion to the increase of the AcCoA concentration. FIG. 15 illustrates the calibration curve with a linear regression equation Y=2.1+57X, r=0.994 (n=15), P<0.0001, Sy/x=0.95. The value of Detection of Limits (DOL) is 1.2.times.10.sup.-12 M/cm.sup.2. Because this sensor is only 0.031 cm.sup.2, hence, its DOL is 37 fM in PBS. The measurements can be extended to an exponential nonlinear model from 2 pM to 0.30.mu.M with y=A1*exp(−x/t1)+A2*exp(−x/t2)+y0, y0=1225.5, A1=−916, A2=-372, t1=0.964, t2=64.5, Chi^2/DoF=17255.7, r=0.98, n=27, 9 levels. Curve fit was not shown. The recovery value using milk at 60 pM AcCoA is 103.+−.2%. The imprecision of milk samples in 60 pM AcCOA is 1.75% (n=12). FIG. depicts the extended plot of current vs. AcCoA concentrations from 2.0 pM up to 0.3.mu.M.

### Example 12

### Quantitation of AcCoA by the DSCPO Method

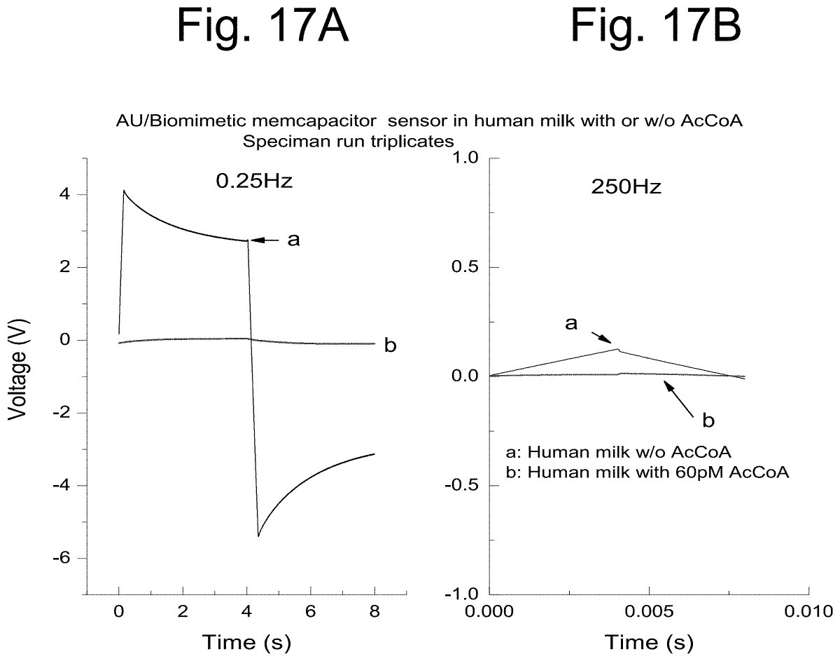

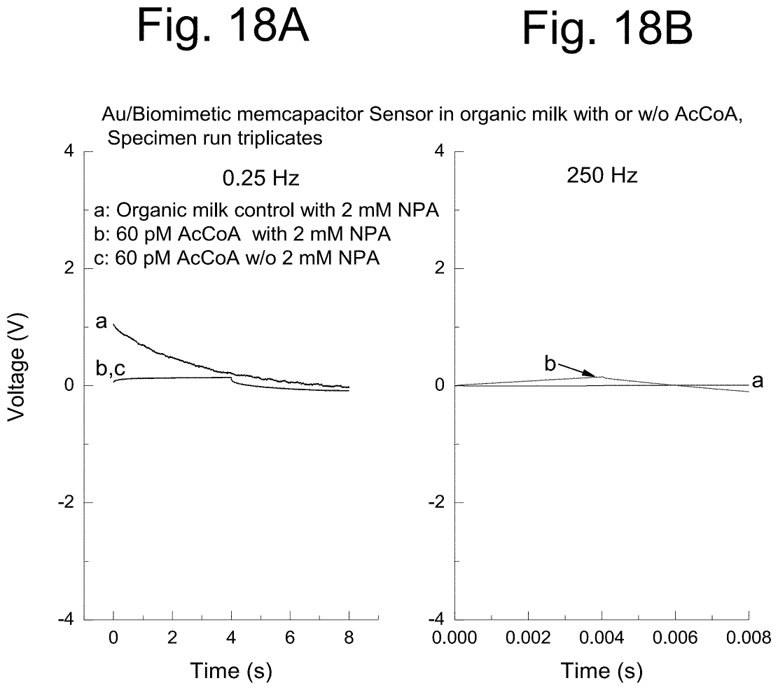

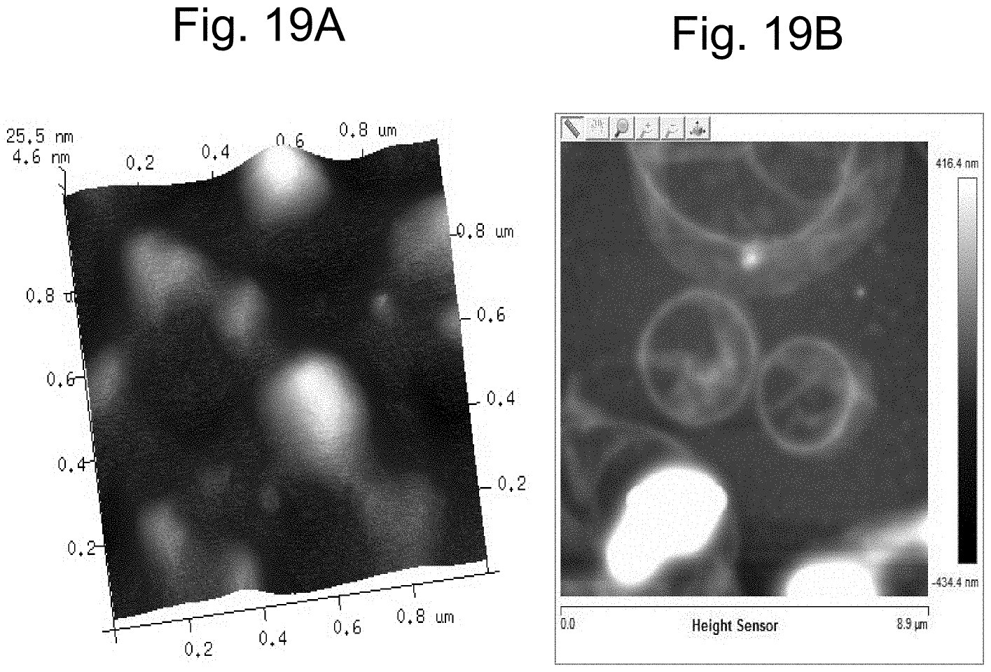

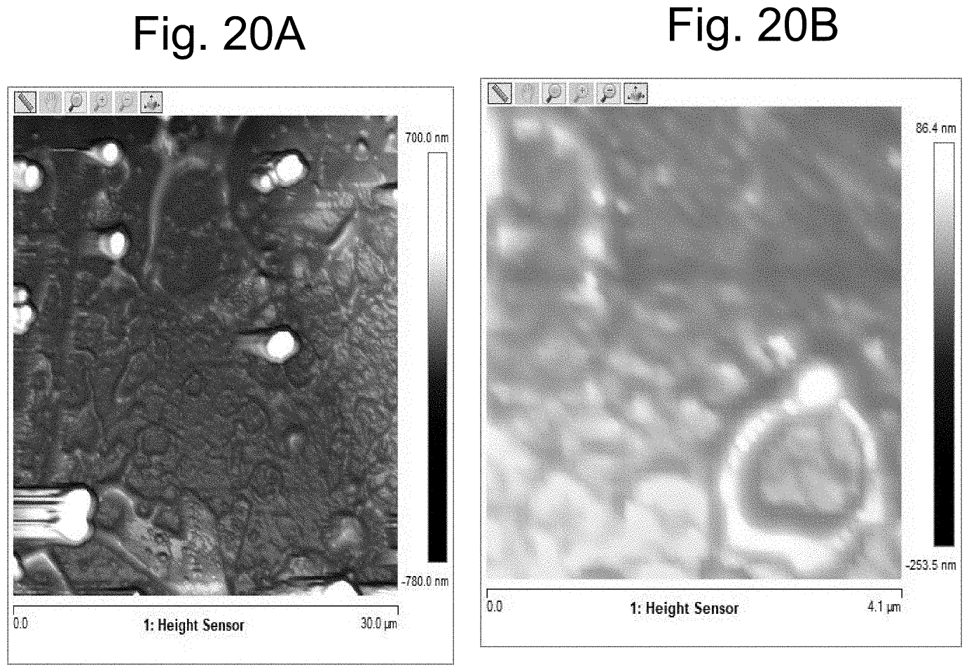

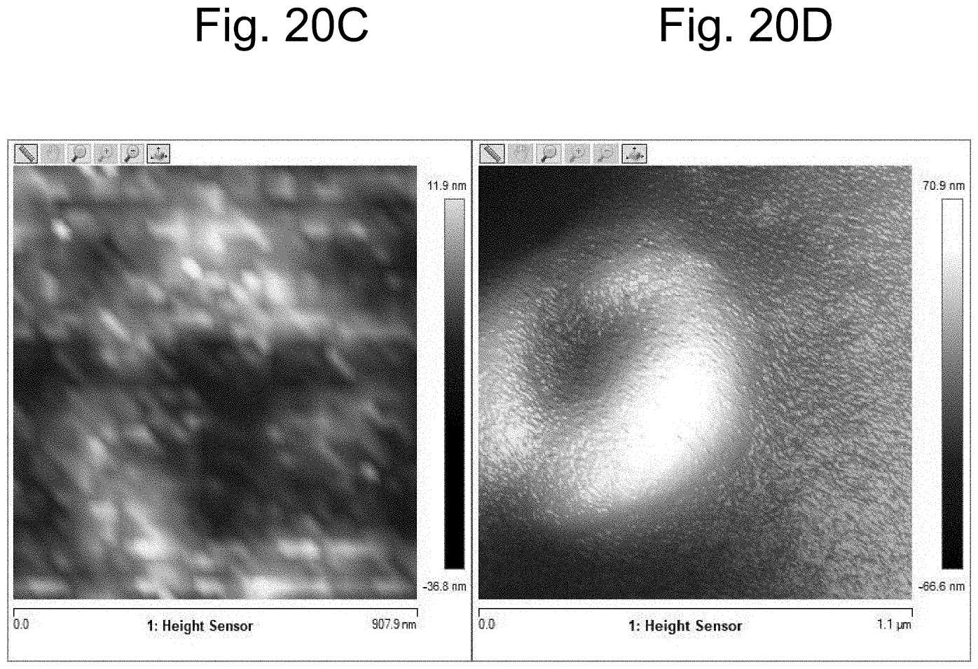

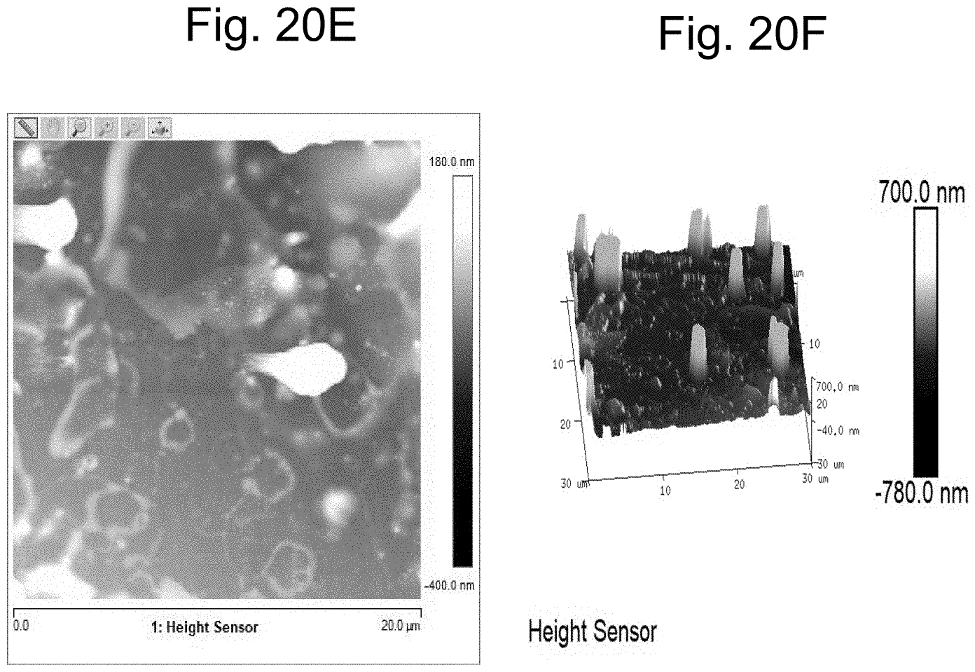

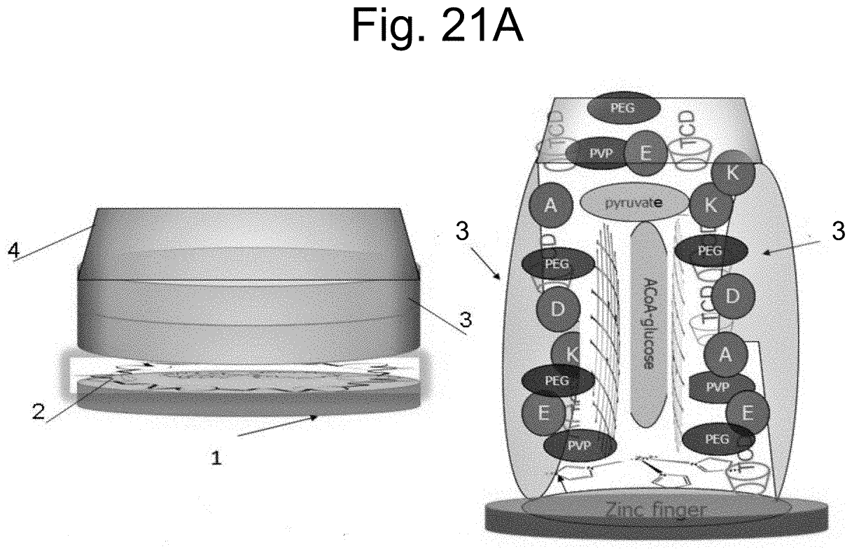

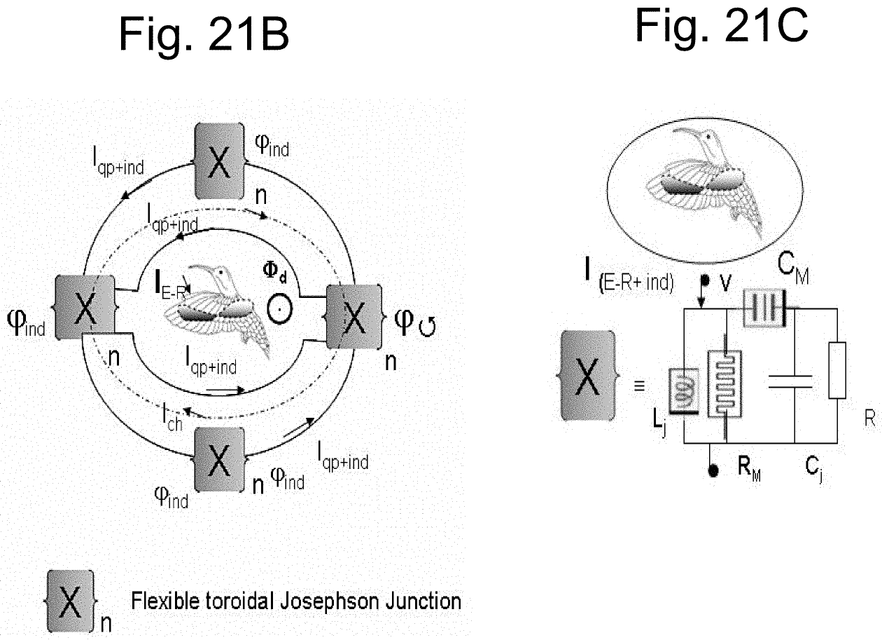

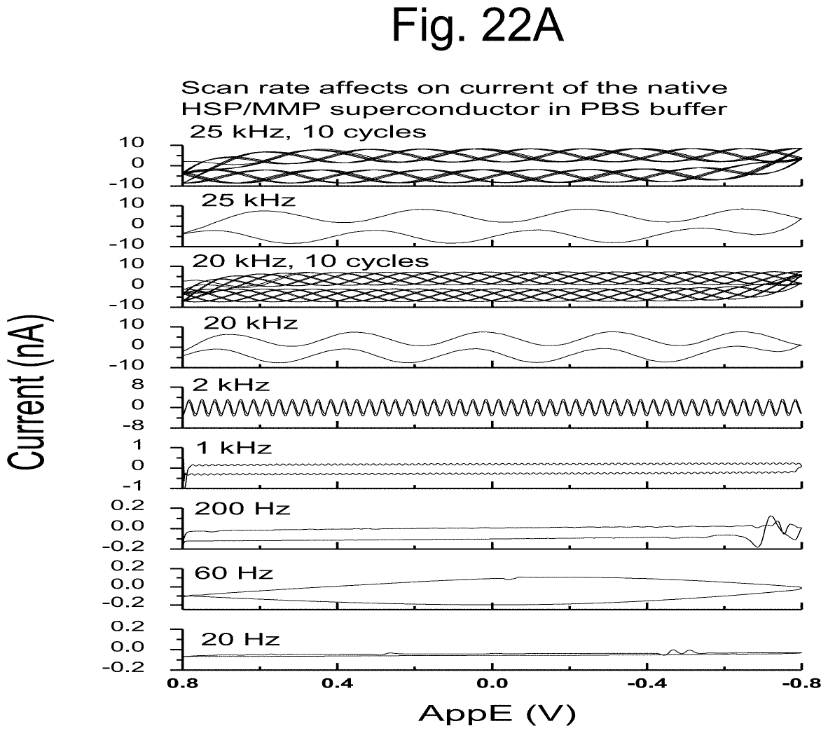

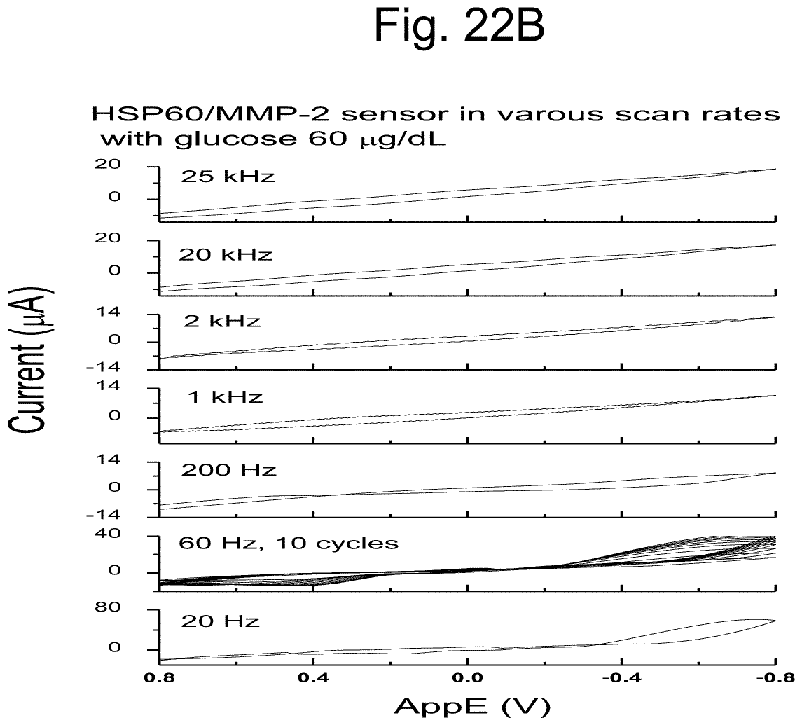

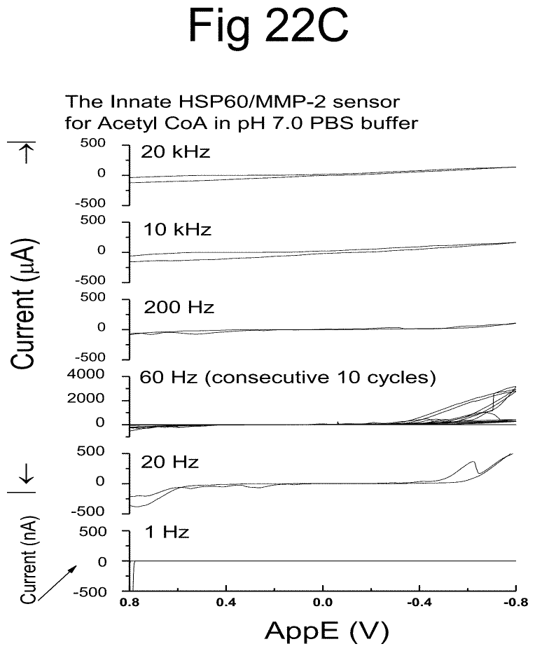

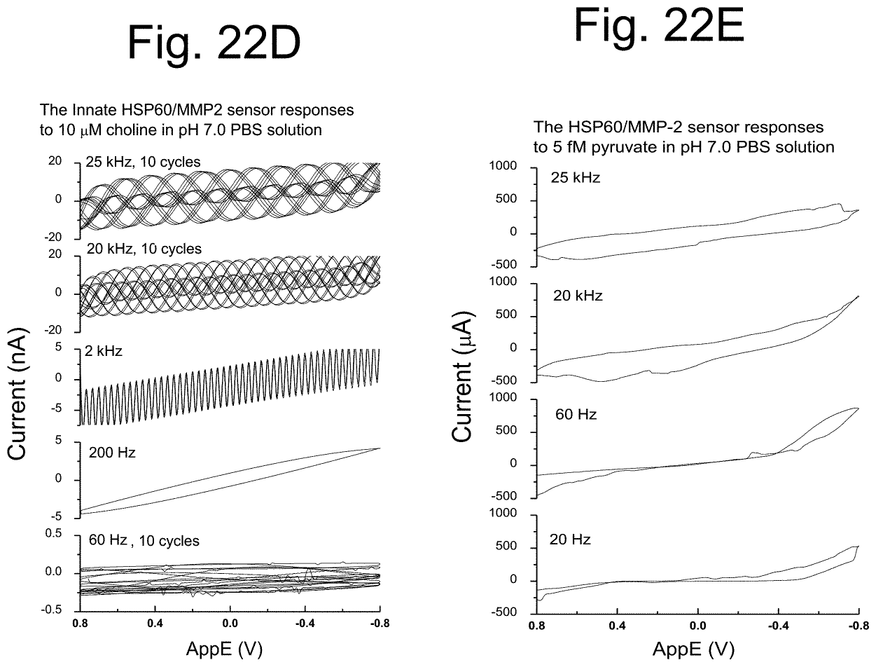

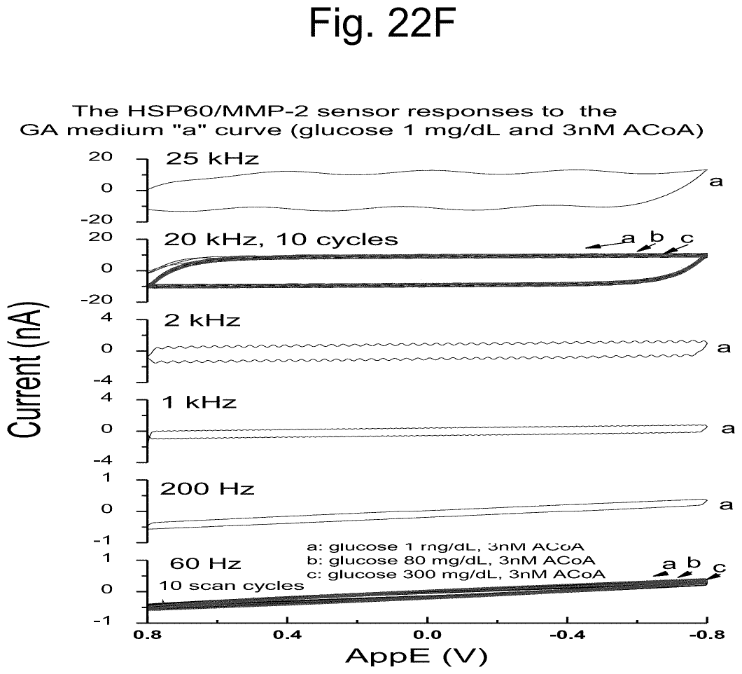

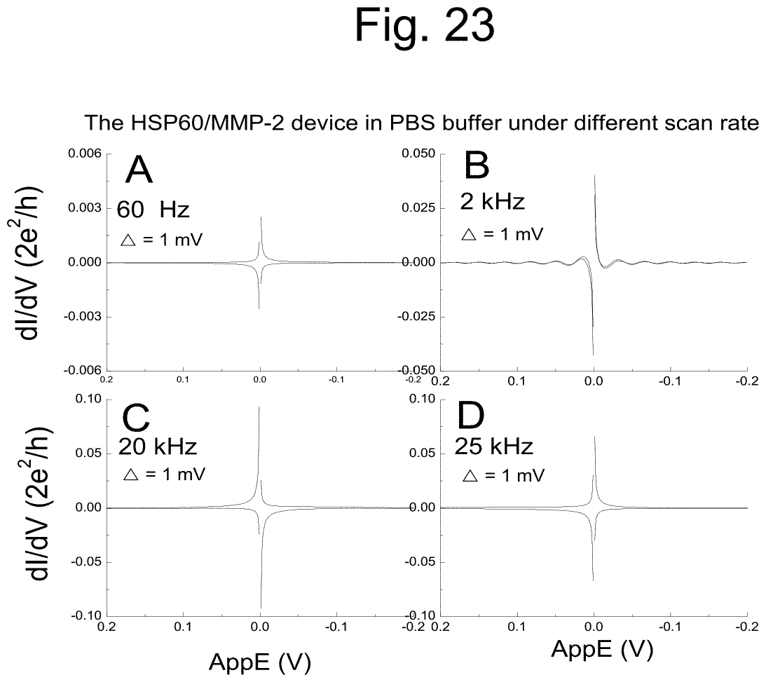

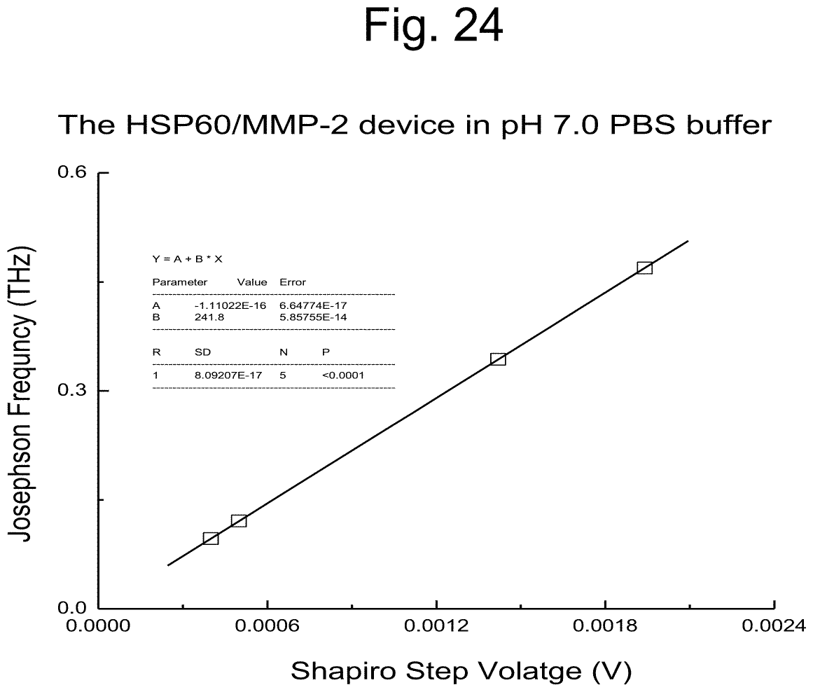

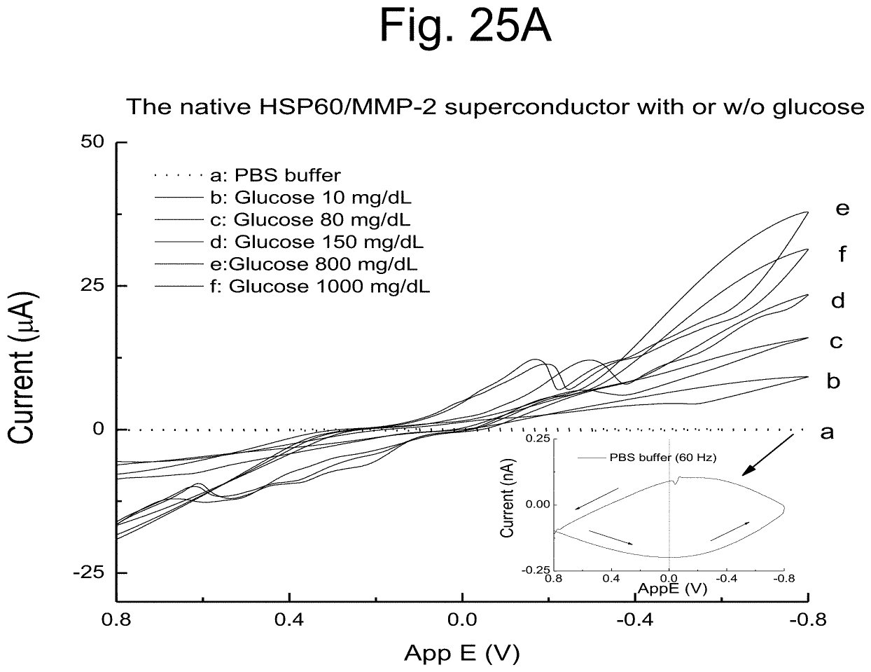

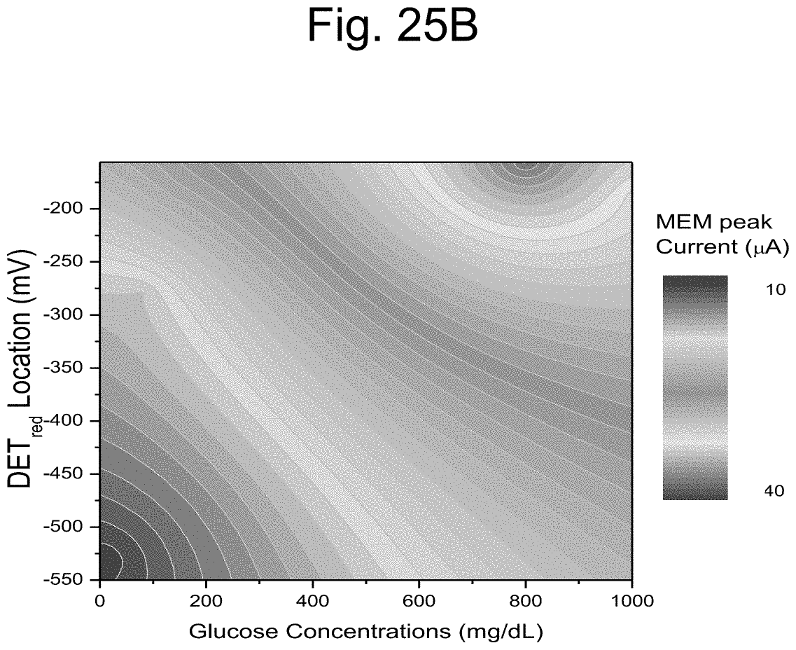

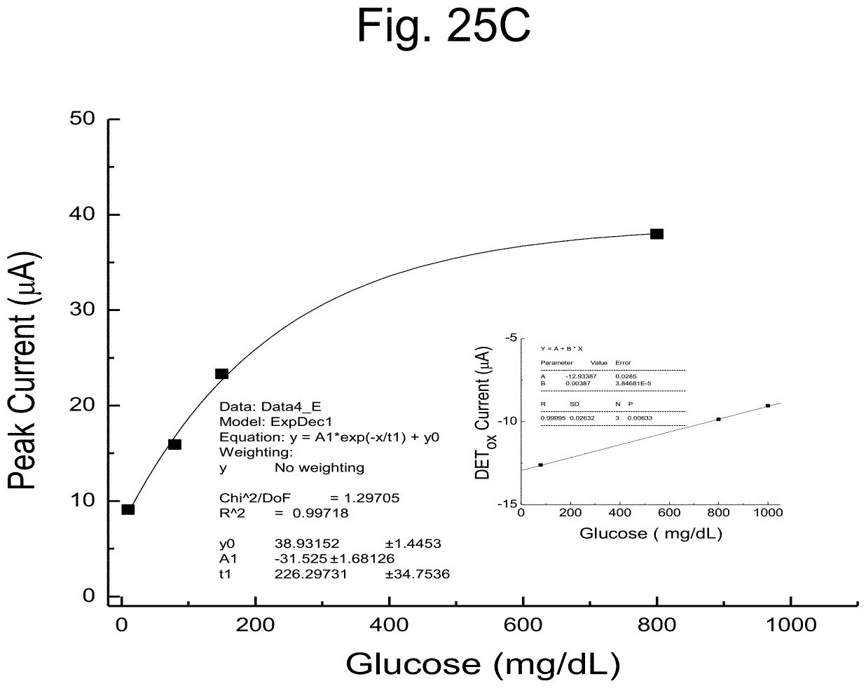

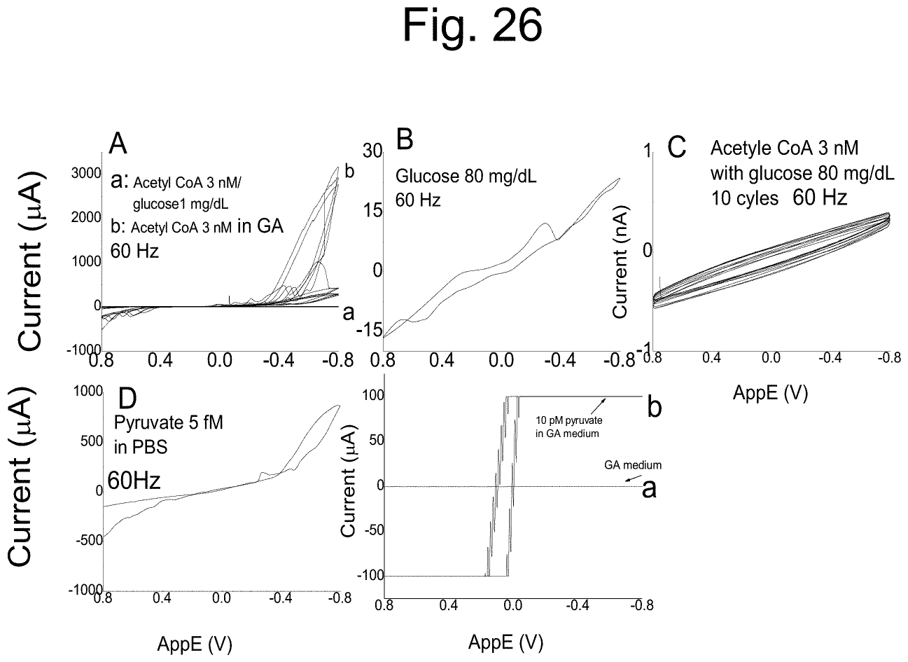

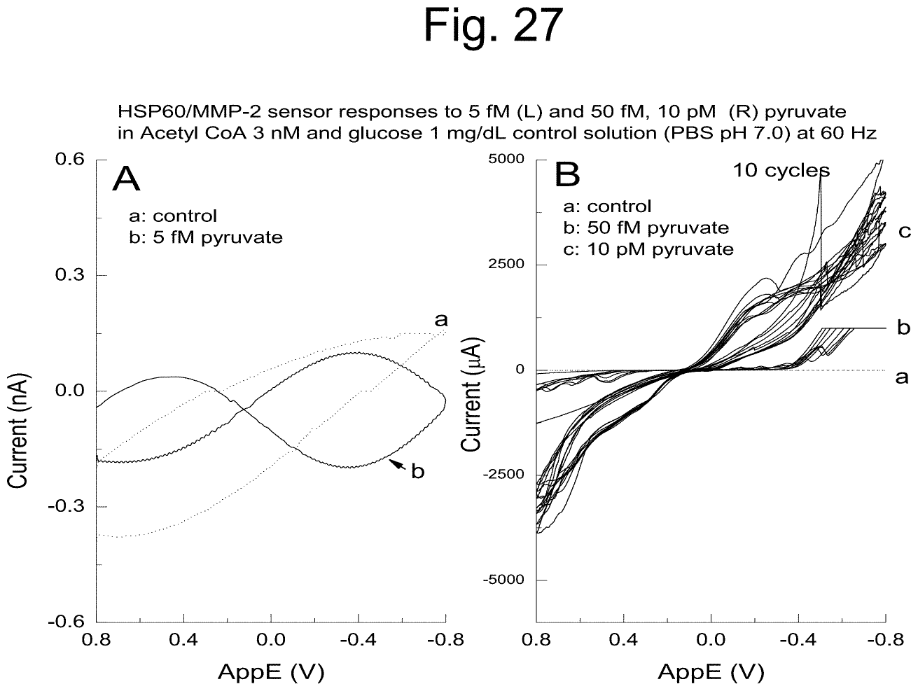

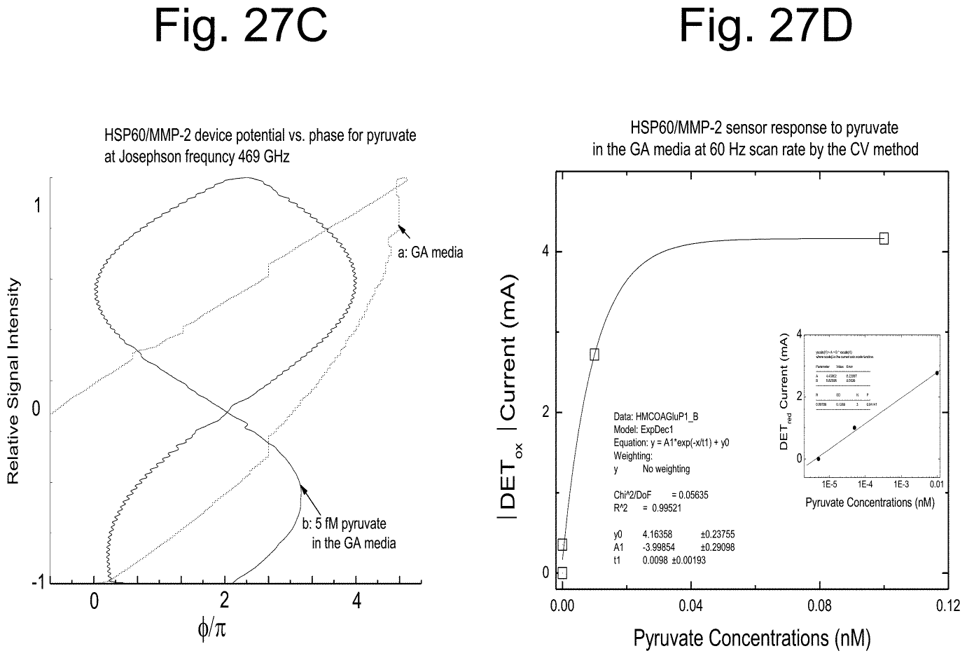

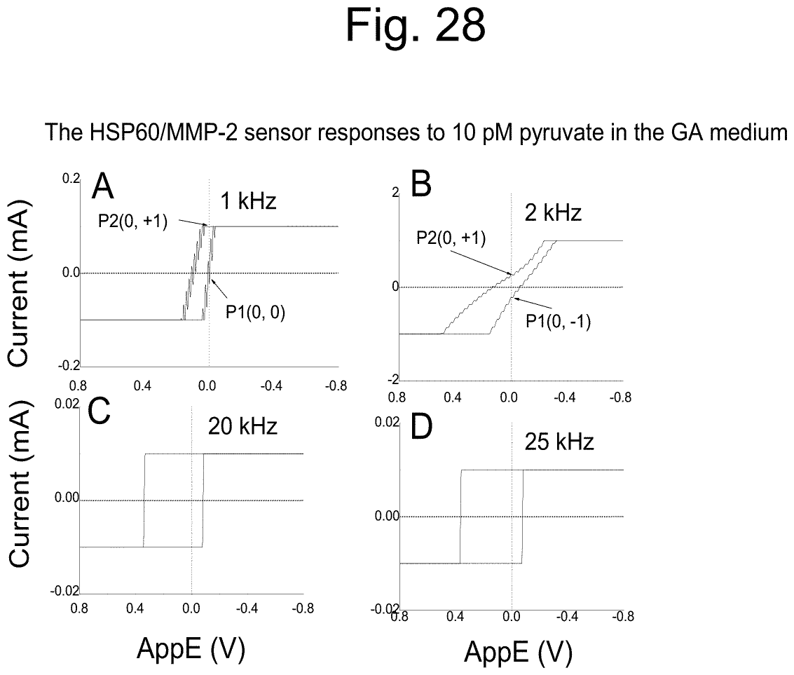

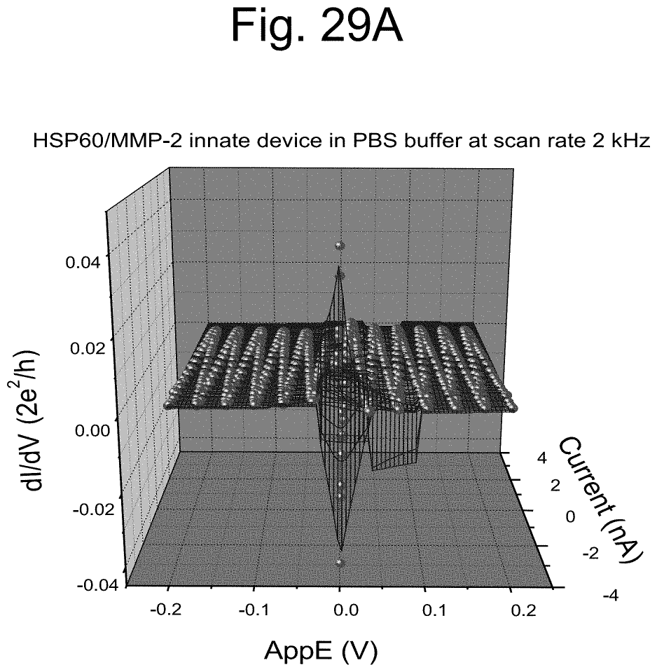

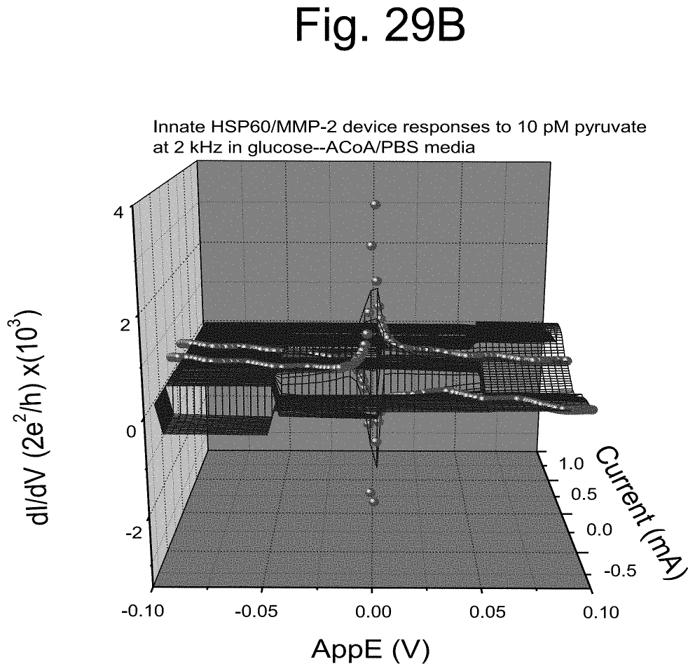

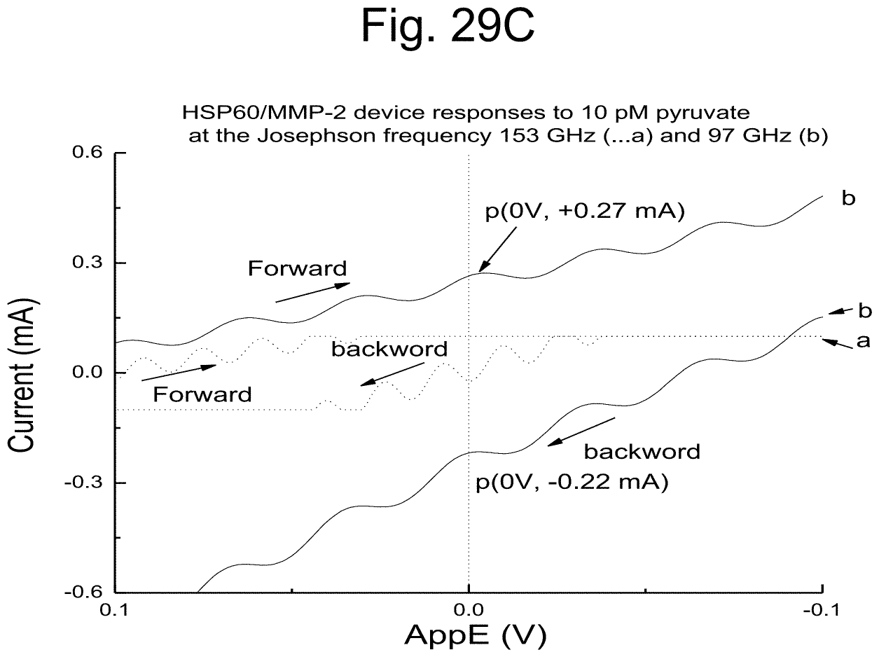

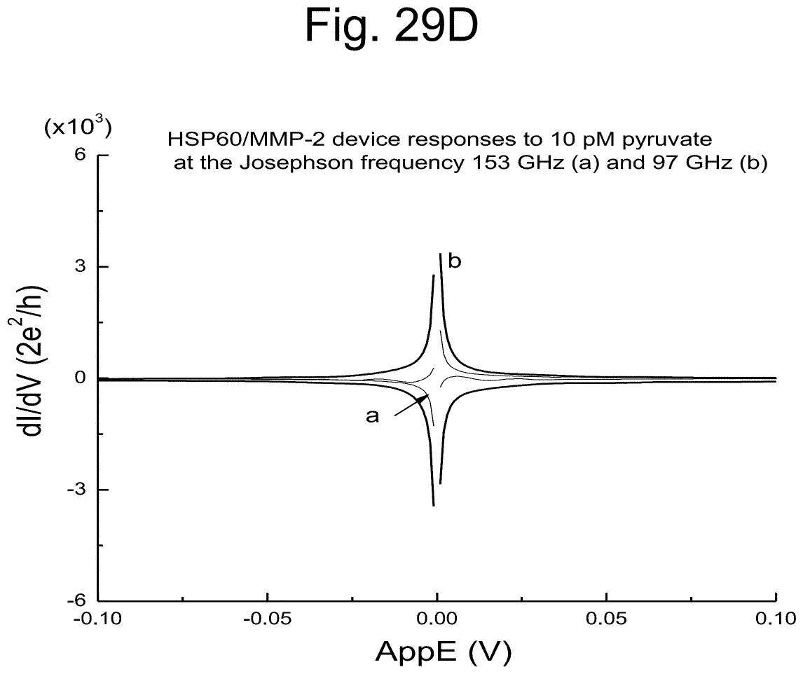

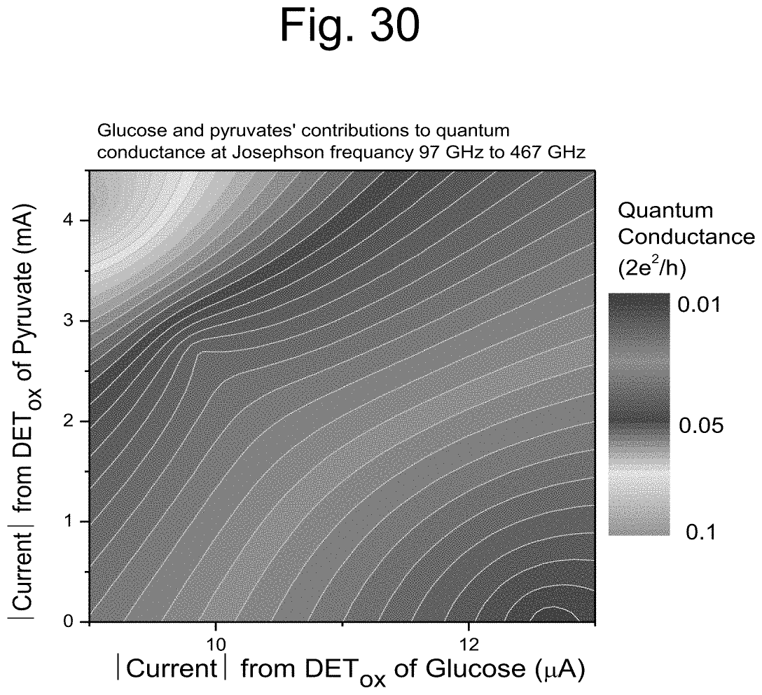

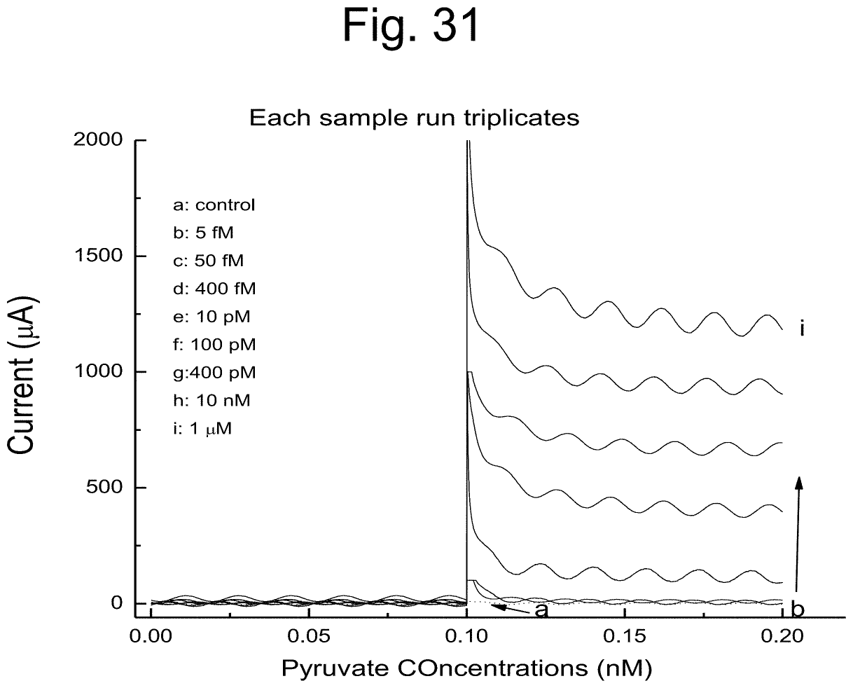

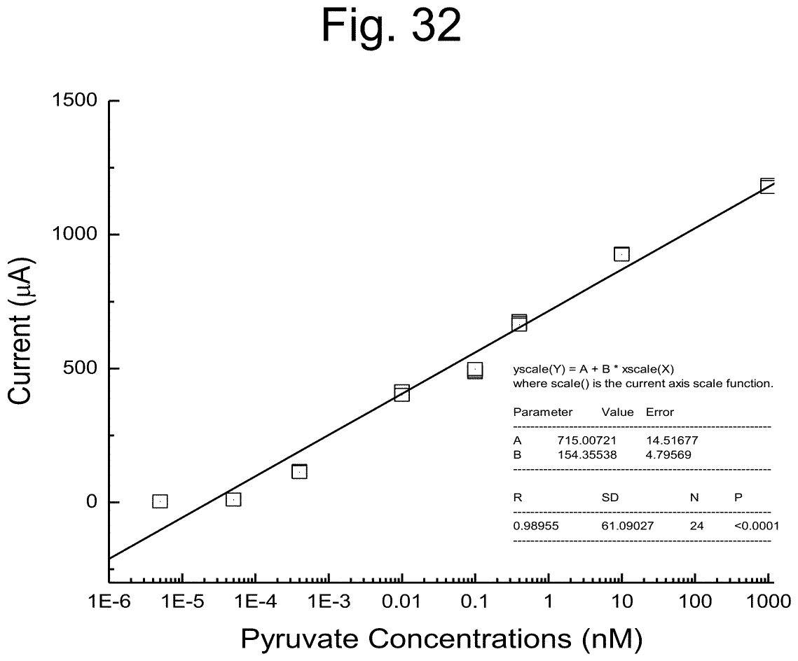

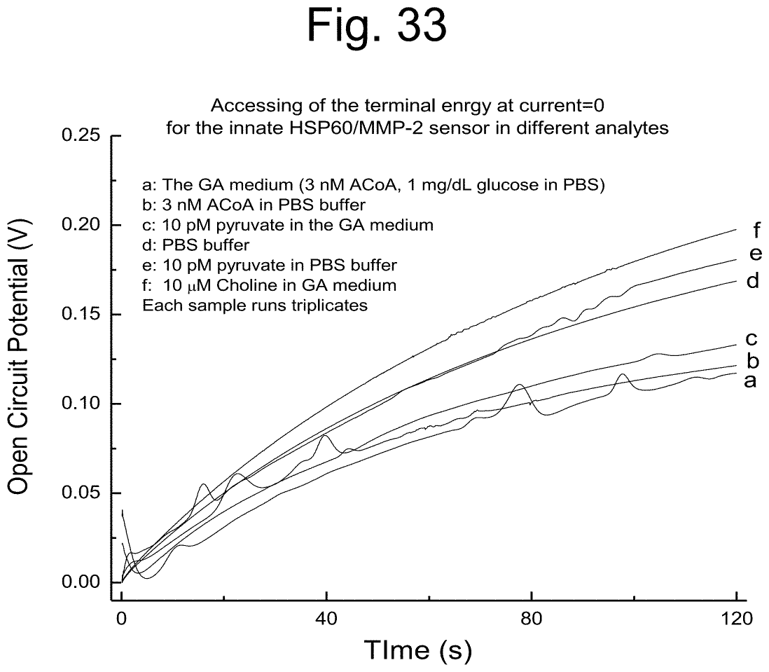

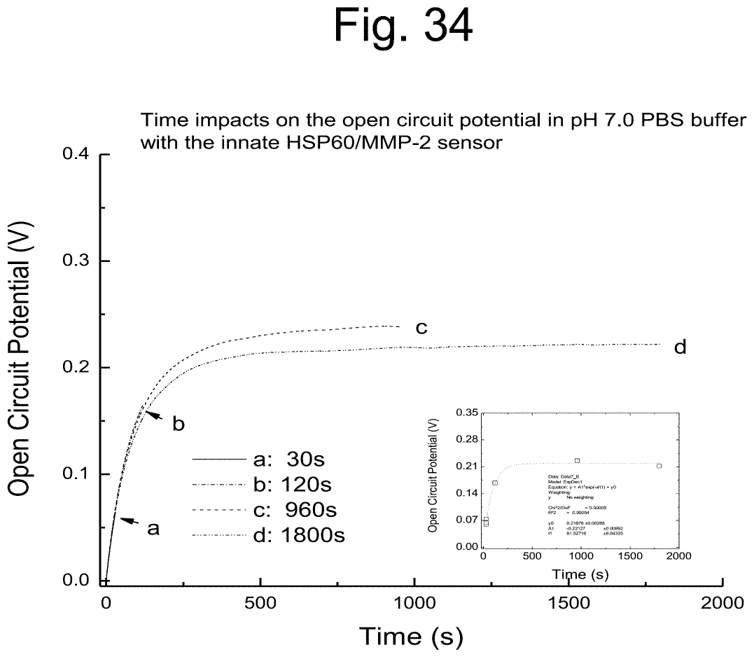

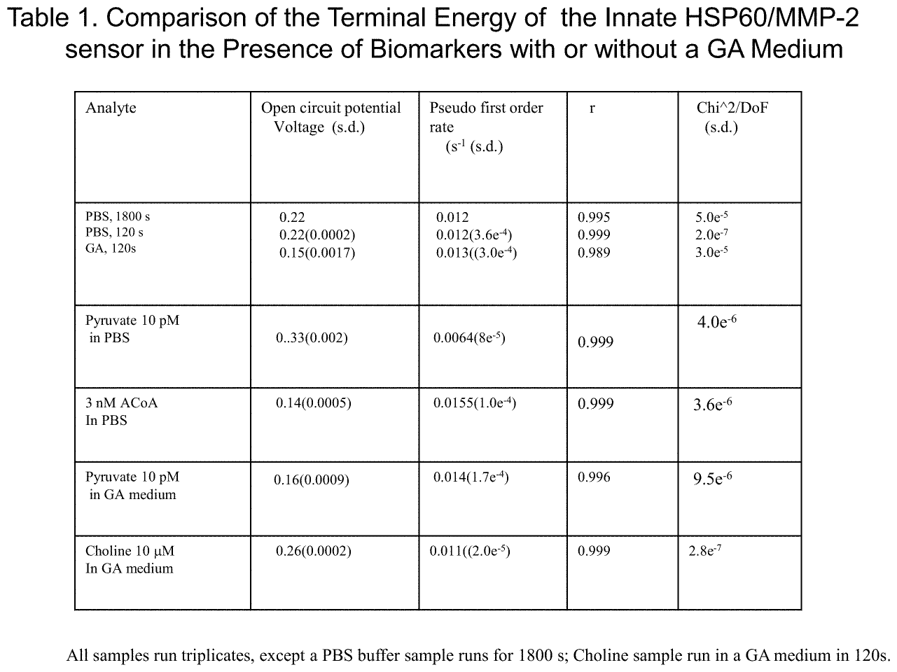

Quantitation of AcCoA and assessing the energy outcomes were conducted by comparing human milk and the USDA certified organic cow milk for infants, both with and without 60 pM AcCoA, at 0.25 Hz and 250 Hz, respectively, using the DSCPO method. The use of the method was disclosed in [00048]. FIG. 17A depicts the 60 pM AcCoA reduced the synapse voltage discharge by 94% at 0.25 Hz in human milk compared without AcCoA. AcCoA reduced more energy outcome at SWS as compared at 250 Hz, as shown in FIG. 17B. Also shown, the good bacteria in human milk boosted the net energy of five-fold, 1.04 nWHr/cm.sup.2 compared 0.19 nWhr/cm.sup.2 of organic milk without AcCoA at 0.25 Hz; and 25.3 pWHr/cm.sup.2 with human milk compared with 37 pWHr/cm.sup.2 of organic milk in the presence of 60 pM AcCoA at 0.25 Hz as shown in FIG. 18A and FIG. 18B. From these results, human milk offers great benefits than organic cow milk for the development of neuronal cells at all frequencies studied regardless of whether it contains AcCoA. The biphasic synapse curves with the highest intensity at SWS over other frequencies are the characteristics of the normal human brain function, and it originating energy for memory consolidation demonstrated using the nanobiomimetic memristor/memcapacitor device using human milk. Using the same device has a destroyed biphasic synapse pattern with so low energy outcome using organic milk as shown in FIG. 18A at 0.25 Hz and FIG. 18B in 250 Hz, with and without AcCoA, indicates there is an urgent need to enrich the probiotic in the cow milk for children. All evidences presented here clearly and convincingly shows that human milk increases the energy available to output to the neuronal cell for further brain developing, and which supports a strong recommendation by the authors to women to seriously consider the advantages of breast-feeding to infant brain development and health

### Example 13

### Potential Application in Superconducting

According to FIG. 4A, the device has potential application in superconducting device at zero-bias with 200 Hz scan rate in PBS solution with .+−.1.mu.A peak superconducting current. FIG. 5A, FIG. 5B and FIG. 14 demonstrated the sine curvatures with oscillation in both situations for with and without analyte, either LPS or AcCoA indicated the toroidal arrays configuration induced the amplified supercurrent at a finite applied V.sub.dc potential (−600 mV) for LPS and (−200 mV) for AcCoA, respectively.

### REFERENCES

[1]. P. O. Magalhaces, A. Mlopes, P. G. Mazzolas et. Al., J. of Pharm Pharmerceutical Sci 10(3), 388-404, 2007.
[2]. M. Daneshiam, A. Guenther, A. Wendel et. al, J. of Immunological Methods 313, 169-175, 2006.
[3]. Y. A. Knirel, M. A. Valvano, Bacterial (Eds), lipopolysaccharides, structure, chemical synthesis and interaction with host cells, Springer, 2011.
[4]. T. Reimer, M. Brcic, M. Schweizer, T. W. Jungi, J. Leukocyte Biology, 83, 1249-1257, 2008.
[5]. G. I. Tsiaoussis, S. F. Assimakopoulos et. al., World J. of Hepatology, 7(17), 2058-2068, 2015.
[6]. LPS: the switch for inflammation in the gut and beyond, www.realfoodforager.com
[7]. A.I. Petra, S. Panagiotidou, E. Haziagelaki, et. al., Clinical Therapeutics, 37(5), 984-995, 2015.
[8]. Anna Struncka (ed), Cellular and molecular biology of autism spectrum disorders, Prague University Press.
[9]. I. M. Chiu, B. A. Heeesters et. al., Nature 501, 52-57, 2013.
[10]. B. Petschow, J. Dore, P. Hibberd, et. al., Annals of the New York Academy of Sceinces, 1306, 1-17, 2013.
[11]. M. Lehmann, O. Wellnitz, R. M. Bruckmaier, J. of Diary Science, 96(2), 889-896, 2013.
[12]. M. Lorna, A. Deleoz, K. M. Kalanetra, et. Al., J. of Proteome Research, 14, 491-502, 2015.
[13]. Chapter five of breast feeding, J. of Tropical Pediatrics, Mother and Child Nutrition in Tropics and subtropics, World Health Organization: Breastfeeding: A brochure for ready reference, WHO, Geneva, 1981.
[14]. N. Khaldi, V. Vijayakumar et al., J. Of Food Chem. 62, 7225-7232, 2014.
[15]. M. L. Marin, R. Avrovo et. al., J. Pediatric. Castroenterol. Nutrition 49(3), 343-348, 2009.
[16]. E. T. Chen, J. Thorten, C. Ngatchou, S-H Duh, P. T. Kissinger, NSTi-NanoTech 2, 107-110, 2013.
[17]. E. T. Chen, J. T. Thornton and C. Mulchi, Jr., Sensors and Transducers Journal, 191(8), 84-99, 2015.
[18]. J. T. Thornton, C. Mulchi Jr, P. T. Kissinger, E. T. Chen, Sensors and Transducers Journal, 191(8), 100-113, 2015.
[19]. E. T. Chen, J. Thornton, C. Ngatchou and S-H Duh, NSTi-Nanotech, 2, 169-172, 2014.
[20]. S. H. Duh, J. T. Thornton, P. T. Kissinger and E. T. Chen, Biotech, Biomaterials and Biomedical: TechConnect Briefs, 172-175, 2015.
[21]. U-M. Bilhardt, P. Stein and G. M. Whitesides, Bioorganic Chemistry, 17, 1-12, 1989.
[22]. A. B. A. Prempeh, A. K. Prince and E. G. J. Hide, Biochem. J. 129, 991-994, 1972.
[23]. T. Kato, J. of Neurochemistry, 42 (4), 903-909, 1984.
[24]. A-R. Kim, R. j. Rylett, B. H. Shilton, Biochemistry, 45, 14621-14631, 2006.
[25]. A. Szutowicz, H. Bielarczyk, A. Jankowska-Kulawy, T. Pawetczyk, A. Ronowsa, Neurochem Res, 38, 1523-1542, 2013.
[26]. Y.Tsuchiya, U. Pham, W.Hu, S-I Ohnuma, I. Gout, PLOS One, 9(5), e97693, 2014.
[27]. Y. Oda, Pathology International 49, 921-937, 1999.
[28]. D. Wu and L .B. Hersh, J. Neurochemistry, 62, 1653-1663, 1994.
[29]. T. Merno-Ramos, A. Vazquez-Calvo, J. Cacas, et. Al., Antimicrobial agent and chemotherapy, 60, 307-315, 2015. Doi:10.1128/AAC.01578-15.
[30]. J. J. Kamphorst, M. K. Chung, J. Fan, J. D. Rabinowitz, Cancer and metabolism, 2(23), 1-8,2014.
[31]. W-P Lu, S. W. Ragsdale, J. Biol. Chem, 266(6), 3554-3564, 1991.
[32]. M. Riera-Borrull, E. Rodriguez-Gallego, A.Hernandez-Aguilera et al., J. Am. Soc. Mass Spectrom, 2015. DOI: 10.1007/s1336-1-015-1262-3.
[33]. E. T. Chen, J. Thornton, C. Ngatchou, S-H. Duh, P. T. Kissinger, NSTi-Nanotech, (3), 115-118, 2013.
[34].E. T. Chen and C. Ngatchou, Clean Technology (3), 204-207, 2011.
[35]. M. Mohammadi, G. McMahon, L. Sun, C. Tang, P. Hirth, Science 276, 955-959, 1997.
[36]. Y. Zhang, N. Su, F. Luo et. al., Int. J. Biol. Sci, 10(9), 1064-1071, 2014.
[37].J. Martinez-Rincon, M. D.Ventra, Y. V. Pershin, Physical Review B, 81(19), 195430-1-195430-7, 2010.
[38].M. D. Pickett, G. Medeiros-Ribeiro and R. S. Williams Nature Materials, DOI: 10.1038/NMAT3510, 2012.
[39] R. Kozma, R. E. Pino, G. E. Pazienza, Advances in neuomorphic memristor science and applications, Springer Publisher, 2012.
[40].M. D. Ventra, Y. V. Pershin, Nanotechnology 24, 255201, 2013.

### Following are the Detailed Descriptions of the Current CIP Invention

### Example 1

### Fabrication of the Nanostructured Organometallic Superconductor/Mem-Element 3D-Cage Innate MMP2/HSP60 Multiple-Layer Membranes

The innate HSP60/MMP-2 device was prepared with two steps: the first step was to form an MMP-2 polymer layer by a self-assembling method with compositions of the innate MMP-2, triacetyl-β-cyclodextrin (TCD), polyethylene glycol diglycidyl ether (PEG) and poly (4-vinylpyridine) (PVP) with appropriate propositions deposited on the surface of gold chips at 37° C. for 96 hours after that followed the wash and dry procedures [3 lb]. The second layer was fabricated by mixture solutions of HSP60, PEG, PVP and TCD with appropriate propositions deposited on the surface of the first layer at 37° C. for 72 hrs. After that, the wash and dry procedures were followed [31b].

The GA medium was freshly prepared in the final concentration comprising of 1 mg/dL glucose (some Section also used 80 mg/dL) and 3 nM ACoA in pH 7.0, 10 mM PBS solution (auto clayed double distilled water for cells), and further went through 0.2 μm filter filtration and degassing.

The morphology of the AU/SAM was characterized using an Atomic Force Microscope (AFM) (model Dimension Edge AFM, Bruker, Mass.). Data collected in TappingMode using silicon probes with a 5-10 nm tip radius and ˜300 kHz resonance frequency (Probe mode TESPA-V2, Bruker, Mass.).

All electrochemical data were collected by the Epsilon working station with the software package for various methods applications (BASi, IN), and the figure plots, and statistical analysis, curve fitting were conducted using the OriginPro software package (OriginLab, MA).

### Example 2

### Evaluation of the Friedel-oscillation in the Superlattice Membrane

Friedel-oscillation is a phenomenon of long-range indirect interactions between electrons on a superlattice surface [19]. Evaluations of the Friedel-oscillation were conducted based on the AFM images. FIG. 19A revealed the Friedel-oscillation in 3D AFM image with an electronic cloud surrounded on the zinc atoms of the toroidal array (200-300 nm diameter pore size) superlattice in the cross-linked innate MMP-2 polymer membrane in the 1.0 mm2 area. FIG. 19B depicts an AFM image in high sensor mode at 8. 9 μm×8.9 μm larger area showing multiple toroidal shaped structures with diameters varied from 1.8 mm to 4.8 mm and the toroidal thickness varied between 50-90 nm. The brightest spots are zinc atoms in the innate protein MMP-2 molecules, and the Friedel-oscillation was observed surrounding the zinc atom indicating the Cooper-pair electrons oscillation with the possible zinc migrations observed because the only zinc atoms came from the MMP-2 protein, there were no zinc ions in our organic cross-linked polymers. Zinc atoms serve as the flexible Josephson junction barriers connection between the superconducting polymers. Images from FIG. 19A and 19B are membranes fabricated by cross-linked triacetyl-B-cyclodextrin (TCD), polyethylene glycol diglycidyl ether (PEG), poly(4-vinyl pyridine) (PVP) and innate MMP-2 protein as the bottom layer. The top layer was fabricated by a properly mixed solution of Heat Shock Protein (HSP60) with TCD, PEG, and PVP on the top of the MMP-2 self-assembled membrane formed a multiple-layer superlattice membrane for creating a Josephson junction superconducting qubit device. FIG. 20A depicts an AFM image of the multiple-enzyme network membrane (30×30 μm²) with multiple-cluster high tower structure having the tower diameters between 500 nm to 2.4 μm, and the towers' height is about 500 nm. The strong Friedel-oscillation from Cooper-pair electron cloud due to the MMP-2 . . . HSP60 networking alignment was observed. The MMP-2's “wedding ring” structure cavity may have 5% alignment with the cylinder structured HSP60, hence formed the unique structure, promoting Cooper-pairs moving from a horizontal 2D surface direction and jumping along a vertical direction of the tower, like industry chimney discharging “electric cloud” from the nano-sized “Tesla towers” observed. In the 2D ground surface, we observed many MMP-2 formed toroidal rings with some of them have zinc atoms on top. FIG. 20B depicts such a perfect “wedding ring” with a diamond sparkling showing the Friedel-oscillation that happened on the toroidal ring filled superlattice flat surface. The thickness in the Z direction is about 70 nm. This observation was similar to the image of FIG. 19B made by MMP-2 cross-linked polymer. FIG. 20C depicts an AFM image of the same membrane in a small area of 907.9 nm×907.9 nm of a diameter 300-360 nm toroidal ring comprising of layered many atoms with a cavity in 20-26 nm depth, and the film thickness is 11.9 nm. FIG. 20D depicts an AFM image of a perfect donut-shape toroidal qubit with an eternal pore diameter of 180-200 nm having an outside diameter of 700 nm and a thickness of 60 nm was observed. FIG. 20E depicts a 2D AFM image with multiple toroidal rings on the superlattice membrane with some of them having Josephson junction zinc atoms on the rings showing the Friedel-oscillation at the horizontal direction, plus, several vertically oriented “Tesla tower” having strong Friedel-oscillation demonstrated the Cooper-pair electron indeed being guided along the towers, and rising vertically discharges the “cloud” of superconducting current in oscillation. The observation of the Friedel-oscillation in the membrane superlattice was a confirmation of the Cooper-pairs' hopping-flip existence [19]. More detailed 3D AFM was depicted in FIG. 20F in 30×30 (μm²) having a tower density of per 45 μm² has one tower, hence the device may have 680-700 multiple-protein network formed Josephson “Switch tower” in switch of the direction of horizontally Cooper-pair moving to a vertical moving along in the wall of the tower. This unique nanostructure SAM membrane with the “two-way” Friedel-Oscillation of Cooper-pair may find utility in multiple-analyte analysis and quantum energy storage and computing.

### Example 3

### An Engineering Working Art Model for the HSP60/MMP-2 Device

A proposed working model used for the illustration of the HSP60/MMP-2 device is presented in FIG. 21A. The left side of FIG. 21A shows the 3D HSP60/MMP-2 membrane comprises of a nano-toroidal structure first layer membrane formed on the surface of the electrode by innate MMP-2/PEG/PVP/TCD, and the second layer is in the alignment of the MMP-2 toroidal array cavities, comprised of HSP60/PEG/PVP/TCD; the top is a poreless cap formed by PEG/PVP/TCD.

The right side of FIG. 21A shows the working model in multiple PPI network between proteins HSP60 and MMP-2, and also the possible PPI between the “Zinc Finger” of MMP-2 and COO— group of TCD and pyridine group of PVP, to form a biomimetic hiding glucose oxidase (GOx) to attract glucose; the “Zinc Finger” of MMP-2, plus TCD, PEG, and PVP may interact with acetyl CoA (ACoA)-lead to form an insulator-like platform to guide the move direction of Cooper-pair, which is moving along the edge of the HSP60 wall; here the “insulator” is not tangible, rather its function is to switch current direction under the impact of a biomarker; the efforts may lead to form a hiding biomimetic pyruvate dehydrogenase (PDH), hence to attract pyruvate at a low frequency [20-28]. Many research reports and review articles were published in the area of PPI network mapping [3, 29-30], but very few, if any, study the local and long-range Cooper-pair DET chain movement in low frequency and its oscillation at high frequency among multiple proteins and multiple biomarkers in a superconductive or a memristive device with flexible Josephson junctions. In FIG. 21A, the left side illustrates the proposed protein MMP-2 . . . HSP60 PPI in the form of DET chain in the toroidal . . . cylinder membrane through a GA medium insulator platform. “1”: the electrode; “2”: MMP-2 cross-linked membrane serves as a zinc finger Cys₁His₃; “3” HSP60 dimer cross-linked membrane; “4”: PEG . . . PVP . . . TCD cross-linked cap. FIG. 21B depicts the symbol of the flexible Josephson toroidal vortex junction. The center “8” shape hummingbird is a symbolic representation of the circular electron-relay system. FIG. 21C depicts the FTVJJ circuit configuration. The results obtained from our experiments may reveal interesting characteristics regarding the PPI/multiple biomarkers' sensing/energy storage and quantum computing information.

### Example 4

### Accessing the Superconductivity and Mem-Element Characteristics

Quantum Conductivity. The hallmarks of the JJ characteristics are (1) at a DC voltage=0,

Iₛ=I_{c} sin(Δφ) (1)

Iₛ is the supercurrent, I_{c} is critical current, Δφ is the phase difference between the waves of two superconductors appears at the DC Josephson junction; (2) at a finite DC voltage, the phase change of the superconducting wave vs. time caused oscillation at the AC Josephson Junction is proportional to 2 eV_{DC}, i.e.,

∂φ/∂t=(2e/h)V_{DC} (2) [31-32]

Here in Equation 2, φ is the phase difference between the waves of two superconductors appears at two sides of the Josephson barrier, VDC is the potential difference across the barrier, and h is the Plank constant (1.055×10⁻³⁴ Js), e is the electron charge.

FIG. 22A depicts the control i-V curve profiles of the HSP60/MMP-2 network protein device in the PBS buffer when the scan rate changed from 20 Hz to 25 kHz, while curves are also shown for 10 consecutive scan cycles at 20 kHz and 25 kHz, respectively, for comparison. There is no hysteresis of memristive observed, but the fractional Josephson junction's vortex inductivity was observed from Eⱼ/E_{c}=1 (Eⱼ is the Josephson energy, and E_{c} is the capacitive energy) at 60 Hz, to Eⱼ/E_{c}>1[33-34] as the scan rate increase to 25 kHz, indicating the phase change induced Josephson energy increased more than the increase of the capacitance energy at zero-bias at room temperature and without a microwave magnetic power applied to the system. Quantum qubit's superposition states were seen between state “1” at v=0, Is>0; state “0” at v=0, Is=0; state “-1” at v=0, Is value <0 from 60 Hz, 2 kHz, 20 kHz and 25 kHz. Phase change was also observed. The curve at 60 Hz shows a reversible pair of direct electron-transfer (DET) peaks with the highest amplitude located at zero-bias, indicates Cooper-pair moves in the superlattice structures (toroidal rings predominantly contributing on the surface over the vertical tall tower does) have eternal electron relay of the receptors at a low frequency than at higher frequency; verse versa, at a higher frequency, the Cooper-pairs have stronger oscillation through the tall tower structure with the 20-50-fold higher superconducting current than that of the DET at low frequency. We call this phenomenon “Cooper-pair's Snowboarding”.

FIG. 22B depicts the i-V curves under the impact of 60 μg/dL glucose concentration in the PBS buffer under the same condition, and using the same sensor. The 60 Hz scan cycles indicate perfect memristive characteristics with the hysteresis cross-point at zero-bias having zero current. We see the DET peaks intensity change as the cycle number changed, that indicate a direct biomimetic enzyme to glucose bio-communication happened at the membrane with a 1.8×10⁵-fold current increase compared with the results of the controls in the PBS medium in FIG. 22A at 60 Hz. As the scan rate increases the memristive was disappearance shown in FIG. 22B, indicates glucose alone lost the DET sensory peak at higher frequency than 60 Hz non-linearly, which matches the memristive behavior [41]. FIG. 22C depicts the i-V curves under the impact of the 3 nM ACoA concentration in the PBS buffer over scan rate 1 Hz to 20 kHz; The memristive peaks are observed at scan rate 20 and 60 Hz, especially at 60 Hz, the current increased 10⁶-10⁷-fold compared with the PBS control samples at 60 Hz in FIG. 22A, that indicates ACoA also direct bio-communicates with the biomimetic choline acetyltransferase (ChAT) receptors of the membrane of the sensor. Comparison of the i-V curves of the DET peaks at 20 and 60 Hz between glucose and ACoA in FIG. 22B and 22C, the intensity of the 3 nM ACoA peak is several orders of magnitude higher than that of the glucose 3.33 μM (60 μg/dL), that indicates the nature of the membrane contains biomimetic ChAT or biomimetic pyruvate dehydrogenase (PDH) complex enzymatic complexation strength is much higher than biomimetic glucose oxidase at 20 and 60 Hz. FIG. 22D depicts i-V curves under the impact of 10 choline in the PBS buffer over the scan rate from 60 Hz to 25 kHz. The flat i-V curves at 60 Hz for 10 scan cycles demonstrate choline has turned the original fractional Josephson junction curve to a topological resistance state compared with the PBS control i-V curve at 60 Hz in FIG. 22A. Choline alone shows no memristive characteristic compared with that of glucose in FIG. 22B and ACoA in FIG. 22C at 60 Hz, that indicates ACoA is in the determination enzymatic step toward ChAT than that of choline, hence choline turns “on” the Josephson superconducting oscillation at scan rate at 2 kHz, 20 kHz and 25 kHz, respectively, to produce more toroidal inductive terminal energy than that of ACoA, and the detail evidence will be shown in the following Section. Hence the i-V curves of choline at high frequency from 2 kHz to 25 kHz show the superconductivity with super-positioning and phase change and nodes in FIG. 22D with the Josephson inductive peaks have intensity between ±2.5 nA to ±12 nA, that is almost in same level as the controls in FIG. 22A at high frequency. Therefore, we may expect choline showing a higher terminal energy than that of glucose and ACoA at an open circuit potential. All Josephson current at zero-bias kept same magnitude compared with the PBS controls at higher frequencies, moreover, with cross nodes, having superpositioning with multiple-states at zero-bias, indicates choline enhanced the memory and Cooper-pairs' entanglement properties of the sensor 3D cavity, it may pave a road for supercomputing.

FIG. 22E depicts the i-V curves under the impact of 5 fM pyruvate biomarker in the PBS buffer over the san rate 20 Hz to 25 kHz. The DET peak current shows the hysteresis of the memristive at a cross-point at zero-bias with zero current, and the peak intensity at −750 mV is 2×10⁷-fold increased at 60 Hz compared with the PBS control sample in the FIG. 22A at 60 Hz, that indicates the biomarker pyruvate is a good candidate to promote a long-range electron-relay at low frequency and may help to accomplish a Josephson oscillation at high frequency if there is a PPI effect between other biomarkers. The i-V curve at 20 kHz, there are 2 DETₒₓ peaks observed, which is very special and meaningful for its ability of complexing with the biomimetic PDH receptors in the sensor membrane compared with the curve of glucose in FIG. 22B and the i-V curve of ACoA in FIG. 22C, and the i-V curve of choline in FIG. 22D at 20 kHz, none has the DET. peak, wherein the 5 fM pyruvate was chosen to be a candidate for working with a molecular platform “Valve” and to activate the “Valve” crossing wideband Josephson frequency.

Developing the Molecular-Biomarker Medium Platform as a Key Component for the Topological Switch “Valve”. FIG. 22F depicts the molecular-biomarker formed medium platform as a key component of a topological switch “Valve” with topological resistance shown under different scan frequencies over 60 Hz to 25 kHz in the i-V curves of the GA medium, which comprises of 3 nM ACoA and 1 mg/dL glucose in the pH 7.0, 10 mM PBS solution. Among the curves, 10 consecutive cycles are shown in 60 Hz and 20 kHz, respectively. Glucose concentration impacts on the GA medium's i-V curves was displayed in two scan rates, 60 Hz and 20 kHz, respectively, 1 mg/dL is for the curve “a”, 80 mg/dL is for the curve “b” and 300 mg/dL is for the curve “c”, while kept the ACoA concentration constant in 3 nM, respectively. The results demonstrate the glucose concentration change did not impact the intensity of the i-V curve, because the i-V curves are superposition at 60 Hz and 20 kHz, respectively, among the different concentration levels over the hypoglycemia, the normal and the hyperglycemia level. The GA medium indeed acted as a topological insulator with negligible background envelop current at 60 Hz, and even at high 20 kHz, the envelop current is still relatively small. As the scan rate increase, it was observed that the toroidal charge energy density caused by the specific capacitance due to the formation of the insulator-like medium with the sensor, has decreased from 67.5 nJ/cm² at 60 Hz to 22 nJ/cm² at 20 kHz calculated based on the equations (4), and (5) in the Example 7. However, the inductance energy density caused by the toroidal flux oscillation is 32 nJ/cm² at 20 kHz compared with 61 pJ/cm² at 60 Hz.

FIG. 23 Panel A shows the curves of quantum conductance vs. potential at 60 Hz, FIG. 23 Panel B is at 2 kHz, FIG. 23 Panel C is at 20 kHz and FIG. 23 Panel D is at 25 kHz at ±1 Δ (±1.0 mV), at room temperature under the condition of without an external magnetic field applied. The intensity of the quantum conductance increases as the scan rate increase from 60 to 20 kHz, after that, the reduced intensity at 25 kHz was observed. FIG. 24 depicts the linear relationship between Josephson frequency and the Shapiro Step Voltage, which the slope gives K_{J} value is that of 241.8, which is equal to 483.5979/2 from a 2 π Josephson periodicity to a 4 π Josephson periodicity of the FFTJJ vortex [35-37].

The Memristor. Memristor is a semiconductor whose resistance varies as a function of flux and charge. This allows it to “remember” what has passed through the circuit [38-41]. G({x},t) which is state dependent

I(t)=G({x},V, t) V(t) (3)

From FIG. 22's i-V curves from the control medium solution samples, there is no hysteresis point observed, and no memristive was observed. However, significant memristive characteristics were observed under the impact of biomarkers, such as glucose, pyruvate and Acetyl CoA, explained in the following examples.

### Example 5

### Sensing of Multiple Biomarkers

Sensing Glucose. The conventional methods for multiple biomarker analysis have been based on multiple antibodies'sandwich ELISA methods, but the protein cross-interference has been a key roadblock hampered the analysis in burdensome time-consuming procedures and low precision. The goal of the article is to seek an approach for developing multiple biomarkers analysis possible methods without using the sandwich antibody that based on the unique superlattice structure and the Cooper-pair's capability through handing out a “tool” to the Cooper-pairs, and stimulate their uncovering potential with sensitivity for analytes and durability for energy storage.

Our attempt to choose appropriate biomarkers, such as glucose and pyruvate as our testing model analytes, was based on the unique nanostructured tall “Tesla tower” on the superlattice toroidal array of the HSP60/MMP-2 membrane. According to literature, inactivated MMP-2 molecules, there are imidazole receptors chelating with zinc ions, the coordination geometry, proton, and electron transfers and the displacement of water molecules formed the long electron-relay chain based on a favorable low AG [42-43]. The chaperoning system is a major component of the anti-stress mechanism in human cells, such as HSP60 molecule interacts with its co-chaperone HSP10 to form a network in mitochondria [16]. There are Ala 10, Asp 11, Glu105, Lys 109, Lys 449 and Glu462 form a complex in the human chaperonin in a 3D football shape in coordination with HSP10 for helping stressed proteins refolding [44-45]. Our cross-linked polymer TCD, PEG, and PVP associated with MMP-2 and HSP60, therefore all of these conditions encouraged us to propose that this HSP/MMP-2 network device may be able to conduct multiple analyte sensing and at the same time to produce energy if we would balance the overwhelming high-frequency oscillation from the Cooper-pairs and enhance the memristive so that the Cooper-pairs might be able to carry on two tasks: sensing multiple analytes and producing JJ superconducting storage energy. FIG. 25A depicts the device responses to various glucose concentrations covered clinically useful range from hypoglycemia, normal to hyperglycemia 10 mg/dL to 1000 mg/dL in five levels through the i-V curves of the Cyclic Voltammetric (CV) method at scan rate 60 Hz compared with the control. The curves are shown glucose several magnitudes promoted significant DET current increase as the concentration increase compared with the control that reflected in the contour plot of the glucose concentration. vs. DETred location and MEM peak current shown in FIG. 25B. We also see the mem peak current increased.

Comparing the Sensitivity. Comparing the sensitivity of glucose detection among the three types of peaks: the memristive peak, DET_{red} d and DETₒₓ peaks, results shown DET_{red} peak current has no trend observed, but DETₒₓ current shows a sensitivity of 0.0044 μA/(mg.(dL)⁻¹) from 80 mg/dL to 1.0 g/dL, and the MEM peak has a sensitivity of 0.0039 μA/(mg.(dL)⁻¹) from 10 to 800 mg/dL, that indicates DETₒₓ peak is more sensitive at higher concentration than that of the Memristive peak, but MEM peak is more sensitive at lower end concentration as shown in FIG. 25C. The insert is for the DETₒₓ peak current vs. glucose concentration.

Sensing Pyruvate and the Glucose . . . ACoA (GA) Platform Approach. The Josephson coupled-superconductor effect is inherent in many superconductor-insulator-superconductor (S-I-S) tunnel junctions if the two sides of barriers are sufficiently thin to allow the coupling energy from the Cooper pair tunneling at the coherent wave state between the two superconductors to exceed thermal fluctuations [30, 48-49]. Majorana zero modes (MZMs) in nonconventional d-wave topological superconductors (d-WTSCs), are extensively studied in recent years [31(a), 37, 50-56] because of their non-Abelian statistics [50-54] and the potential application in topological quantum computation (TQC) [27, 53-54]. Our group reported a self-powered multiple flexible toroidal vortex Josephson junction (FTVJJ) array superconductive/mem-element superlattice quantum bit (SULQUBIT) device for quantum computing with non-volatile memory and non-dissipation energy storage in room temperature within one device assembly. The device comprises of multiple layer organo-metallic cross-linked polymers having various superlattice structures, which works under normal pressure without an applied external magnetic field based on a d-wave electron—relay in the membranes that initiated and promoted Cooper pairs coherently quantum transmitting and amplifying waves in changing phases within and across the FTVJJ barriers, that comprised of a d-wave topological superconductor (TSC)/a 133 μm thickness dielectric insulator/a nanopore semiconductor with superposition states at zero-bias by the Majorana fermions induced proximity was reported [27, 56]. The paramount challenge facing the multiple biomarker screening and monitoring is the requests of limited using antibody (because for some cases of pandemic diseases, such as coronary virus Covid-19, there was no antibody is available). We thought an approach of solely rely on the presence of Cooper-pair of multiple PPI induced proximity in the JJ vortexes may not enough to carry on the tasks, because the lack of an appropriate memristive characteristic from FIG. 22 was identified.

As we know, glucose-derived pyruvate is a principal source of acetyl CoA (ACoA) in all brain cells, through pyruvate dehydrogenase complex (PDC) reaction [57]. The human brain consumes 20% of whole-body oxygen and glucose through glycolytic pathway yields pyruvate, a key precursor for ACoA, which feeds the TCA cycle, herein ACoA activities in brain mitochondria cells, which is 4-10 times higher of ACoA than non-excitable tissues [57]. Our group reported a nanostructured biomimetic PDC sensor was capable to selectively direct detect single brain cancer cells and could mimic an “ATP Lid” based on a self-assembled membrane (SAM) comprising of mono imidazole derivative dimethyl b-cyclodextrin (mM-β-DMCD) cross-linked with TCD, PEG, PVP and o-nitrophenyl acetate [22, 58]. The major dominant driving force is the “snowboard jumping” of the Cooper-pairs' momentum, which shows a strong oscillation in FIG. 22 from 2000 Hz to 25 kHz in the buffer solutions. FIG. 21 on the right-hand side art model illustrates our approaches to overcome the problem: (1) use glucose as a “ladder” lean onto the “Tesla Tower” because above section FIG. 25A shows glucose induced DET peaks at 60 Hz; (2) choose ACoA as a cofactor helping glucose forming a topological platform media, that Cooper-pairs may recognize the platform and “willing” to be led by the “glucose-ACoA helper” for a quantum diving down to the sensor's toroidal array surface from the platform, and demonstrate its topological behavior; (3) Finally the Glucose . . . Pyruvate . . . Acetyl CoA (G . . . P . . . A) formed a long-range electron-relay chain that promoted the Cooper-pairs either capable to be topologically quantum conductive or capable to be a memristor in remembering of the past event [34, 41, 47]. It is not surprising, this multiple analyte G . . . P . . . A chain approach, i.e., the PPI network approach, matched with the common cell energy metabolism analyte chain, it utilizes multiple enzymes for conducting hydrolysis and oxidative reactions and produce energy that has been an inspirational teaching.

### Example 6

### Engineering a Valve Switches Between Superconductive and Memristive State

Pyruvate Activated the GA Medium. Based on the i-V curves in FIG. 26 Panel A shows the device has orders of magnitudes increased peak current in memristive characteristics in the presence of 3 nM ACoA (curve b) compared with the curve “a” having a flat line of the i-V curve reflected the topological resistance increased significantly in the presence of the GA medium, that indicates ACoA alone promotes activating the PPI of HSP60, based on the hiding strong expression of the pyruvate dehydrogenase complex (PDC) enzymatic activity (the PDC may be formed by the histidine groups in the MMP-2 and cross-linked with PEG, PVP, and TCD through hydrogen bounding and π-π interaction, or hydrophobicity interaction which enabled topological resistance, that expels hyperglycemia's activation of MMP-2, in turn, the GA medium may suppress the potential increase of the enzymatic activity from the biomimetic glucose oxidase. Together the GA medium acted as an electric insulator to guide Cooper pairs either go to the road as a topological quantum superconductor or go to the road as a memristor in the presence or absence of pyruvate; in FIG. 8 Panel B, the i-V curve in the presence of 80 mg/dL glucose alone shows a DETₒₓ peak intensity is 0.3% of the intensity of curve “b” with 3 nM ACoA in FIG. 26 Panel A. In FIG. 26 Panel C, an i-V curve shows the second evidence of a topological resistor's behavior over 0.8 V to −0.8V during 10 cycles of consecutive scans at 60 Hz in the presence of a GA medium, that comprises of 80 mg/dL glucose and 3 nM ACoA, that supports our hypothesis: the GA medium platform promotes the PPI between MMP-2 and HSP60 by selectively suppress glucose's activation of MMP-2, and promotes HSP60's normal function. Quantitation of pyruvate under antibody-free and label-free conditions might be expected. In FIG. 26 Panel D, there was no DETox peak observed with pyruvate alone in the PBS buffer, compared with the i-V curve “b” in the presence of 10 pM pyruvate with the GA media, which shows ±80-fold enhancing supercurrent at zero-bias at 1 kHz compared with the zero current curves “a” from the GA medium in FIG. 26 Panel E. Herein, this HSP/MMP-2 device may be used as a model for mimicking mitochondria's energy production.

In FIG. 27 Panel A curve “b” in the presence of 5 fM pyruvate in the GA medium shows hysteresis characteristics of the memristor-like behavior compared with the GA control medium. FIG. 27 Panel B shows the DET current increased significantly as the pyruvate concentration increase from 50 fM to 10 pM in 10 consecutive scan cycles compared with the GA control, and the signal was in orders-of-magnitudes increased compared with the controls. FIG. 27 Panel A curve “b” and Panel B curve “b” and “c” show the device is capable to measure the biomarker pyruvate from 5 fM, 50 fM to 10 pM, (100 pM was not shown) in the GA media solution with a 60 Hz scan rate compared with the GA control media. Now the Cooper-pairs demonstrated they are memristive at low 60 Hz that enabled us to conduct amperometric quantitation at a well-defined mild applied potential. FIG. 27C shows the curve of the relative signal intensity vs. phase change in the presence of 5 fM pyruvate in the GA media at 469 GHz Josephson frequency with a signature hysteresis cross point and a 4 π d-wave Josephson periodicity rather than 2p compared with the GA media control. The success of training Cooper-pairs quantum jumping “up”-oscillating, and a “10-meter Diving” from the GA platform leads us to believe the toroidal array JJ structure and the “Tesla mini-tower” helped Cooper-pair's two-way superconducting/memristive switch in a 3D fashion, even the original i-V curves of the PBS buffer did not show such capability, through the platform approach, Cooper-pairs' potential can be realized and demonstrated. FIG. 27D shows the sensitivity of the tested DETₒₓ current related to pyruvate concentrations over 5 fM to 0.1 nM is 102 mA/nM, which is 1.3×10¹²-fold sensitive than that of glucose testing. The insert in FIG. 27D is for the calibration curve of DET_{red} vs. pyruvate concentrations.

The power of forming a long-range direct electron-transfer relay of the glucose . . . pyruvate . . . ACoA communicated with receptors of multiple-enzymes in the HSP60/MMP-2 superlattice membrane by inserting pyruvate molecules into the GA medium platform demonstrated a molecular state valve's switch capability between the memristive state at 60 Hz as shown in FIG. 27 Panel B to the superconductive state at zero-bias with the phase change and superpositioning as shown in FIG. 28 Panel A, Panel B, Panel C and Panel D over 1 kHz to 25 kHz in the presence of 10 pM pyruvate in the GA medium compared with controls. The state valve guided the Cooper-pair electrons accomplished not only conducted a horizontal direction move, but also a vertically move along the HSP cavity wall at the Josephson frequencies from 97 GHz to 343 GHz with superposition at p(1, 0) and p(−1, 0) and p(0,0) state at zero-bias, while either pyruvate along or GA medium along cannot accomplish such a unique function. The conventional teaching about the fuel pathway in a biological cell from glucose's glycolysis by the multiple enzymes in cytoplasm to form pyruvate molecules, then pyruvate was converted to ACoA by the enzyme PDC in the mitochondria cell has been in linear electron transfer chains. There was no proposals or suggestions appear in the literature to envision of the MMP2 and HSP60 in the intracellular region to cooperate impacting on the fuel pathway DET chain in a 3D fashion, nevertheless we knew MMP-2 enters mitochondria may cause HSP60 concentration decrease in the hyperglycemia condition, and it decreases electric conductance in the junction membrane of mitochondria, and led to retinal endothelial cell disruption, even further damages DNA of nucleus [3]. Our discovery in the PPI of the MMP-2/HSP60 toroidal-tower nanostructured double-layer membranes expanded the horizon regarding how the Cooper-pairs participated in the DET relay chains with the help of the active molecular valve, which might open opportunities for new tools of speedy up developing new devices and pharmaceutical drugs.

### Example 7

### Topological Quantum Conductance Due to Pyruvate's Participation in the Majorana Zero Mode

Stern's group reported the observation of Majorana bound states of Josephson vortices in topological superconductors, and the equations of three types of energy contributions to the Josephson vortices in a long circular junction in a Sine-Gordon system was published [59]. The Josephson junction energy was from the Cooper pair, the magnetic energy was from the inductivity of the circular vortex, and the charge energy was from the SIS quantum capacitor-like device [59]. The vortex suppression of the supercurrent effect also was considered in the equation. However, there was no further analysis of how each component energy contributes to the system superconductivity from the experimental data. Cosmic's group reported seeing the vortex in a Josephson array based on a fractional Josephson Effect in the vortex lattice [60]. The Hamiltonian of the Josephson Junction Array (JJA) was given in the combinations of the first part of charging energy obtained from all arrays and the second part of the Josephson Effect energy [60]. Our group's prior work had experimentally quantified the contributions from the fractional superlattice qubit to the device's kinetic energy and the potential energy to the quantum conductance by using the 3D dynamic map method at room temperature without external magnetic field applied [37]. The modified Sine-Gordon system energy for our d-wave vortex array is:

Eⁿ_{JJA}=(½)C⁻¹ᵢ(Q−en_{1 . . . i})² (4)

Eⁿ_{L}=(½)μ₀N²_{n=1 . . . i}I²_{n=1 . . . i} (5)

where Eⁿ_{jjA} is the charge energy of Josephson Junction arrays at n=1 . . . i; Q is the charge, C is the total capacitance at n=1 . . . i, en is the n quantum particles at 1 . . . i data point with an energy periodic in h/e for Josephson effect for d-wave [61]; Ell is the Inductive energy induced by the circular toroidal array. N is the turning number around the toroidal porous at n=1 . . . i, A is the cross-sectional area of the porous, L is the length of the wending, μ₀ is the magnetic permeability constant in free space; I is current. The toroidal arrays are in series connected. Recent publication from our group regarding the FFTJJ multiple-variable study in 3D dynamic maps was presented in the literature [37]. The 3D mapping method used in this report is to show the Majorana Zero Mode (MJM) at the Fermi energy level related to the peak current, zero-bias, and the quantum conductance visually. Results from the evaluation of the pyruvate's promotion of quantum conductance at a higher frequency are further presented in a 3D dynamic map in FIG. 29A. FIG. 29A shows there is a zero-energy Fermi surface with Cooper-pairs transmission crossing the JJ at Zero bias having the multiple states in superposition in the PBS buffer only. As a comparison, the superposition is also presented in FIG. 29B with 10 pM pyruvates in the GA media, the quantum conductance was orders of magnitude higher (74,667-fold) than that of the control. FIG. 29C shows the superpositioning of the states in the plot curves of supercurrent vs. potential with 10 pM pyruvates in the GA media at 97 GHz compared at 153 GHz of the Josephson frequency. FIG. 29D shows the 2D plot of the quantum conductance vs. potential at zero bias in the presence of 10 pM pyruvate at 97 GHz compared at 153 GHz of the Josephson frequency, in the GA media.

### Example 8

### Assessing Multiple Biomarkers' Contributions to Quantum Conductance

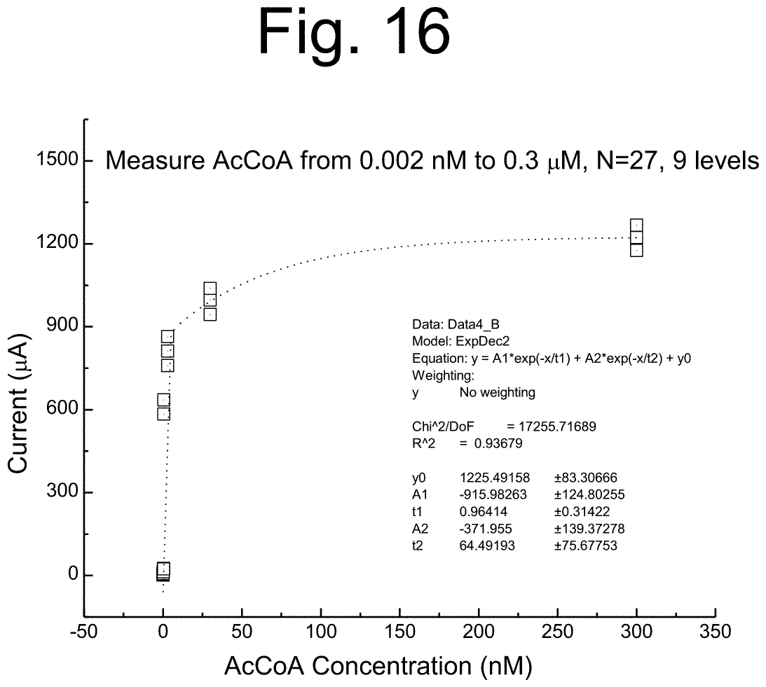

Based on the results obtained from the i-V curves of DETₒₓ peak current of glucose alone from 80-1000 mg/dL(4.46 mM-55.7 mM), without the GA medium at scan rate 60 Hz shown in FIG. 25A, and the results from the i-V curves in the presence of pyruvate (50 fM to 100 pM) with the GA media from FIG. 9B to FIG. 28A-FIG. 28D at Josephson frequency 97-467 GHz, a contour map is presented in FIG. 30 with the Z represents the quantum conductance covers Josephson frequency from 97 GHz to 467 GHz. FIG. 30 shows the higher quantum conductance associated with 50 fM to 100 pM concentration pyruvates having an absolute value of 0.35 to 4.16 mA current of the DETₒₓ peak, while the entire glucose concentration range has a small contribution to the lowest values of conductance that indicates the GA media platform acted as the topological insulator, it leads Cooper-pairs jumping-diving in a long-range tunneling fashion along the toroidal vortex wall. Pyruvate has a wide range of concentration contributed to the higher values of quantum conductance.

### Example 9

### Quantitation of Pyruvate Using the Chronoamperometric Method (CA)

Based on our innovative multiple protein network approach associated with the GA medium, we were able to direct quantify pyruvate without use antibody by the CA method. FIG. 31 shows the curves of current vs. time profiles over the pyruvate concentration from 5 fM to 1 μM compared with the GA control. The inserts are the enlarged control and a curve with 5 fM pyruvate. The semi-log plot of the calibration curve was shown in FIG. 32. FIG. 32 shows the regression equation y Scale (y)=715.0+154.3*log(x), n=24 (8 levels), r=0.99, S_{y/x}=61, p<0.0001. The Detection of Limits (DOL) is 13 aM over the measured range with a Relative Pooled Standard Deviation (RPSD) value 1.4%

### Example 10

### Accessing of the Terminal Energy Using the Open Circuit Potential Method

Under the inspiration of our prior works, we were able to use the Open Circuit Potential (OPO) method to access a superconductive device's self-powering capacity as an energy storage device [27], wherein we thought the spontaneous discharged voltage pulses indicate there were an embedded power in the device which have self-powering the quantum computing characteristics promoted by the presence of biomarkers, which associated with the GA medium, formed the “State Switch Valve” without a need of a microwave power supply; nor does it consume any energy, as shown in FIG. 33. FIG. 33 depicts the spontaneous discharged voltage curves vs. time at current=0 under the impact of pyruvate, choline and ACoA with or without the presence of GA medium, respectively, compared with different controls of the biomarkers in the PBS buffer. Curve “a” shows the GA medium has the lower peak intensity compared with the PBS buffer alone, that indicates the GA median blocked the energy at the equilibrium state, and the curve “f” shows 10 μM choline has the highest peak intensity in the GA medium, that indicates this sensor might be acted as potential neural prosthetics with choline in the presence of the PDC or biomimetic PDC enzyme, that produces significant magnetic flux at current=0, we may envision that a nominal cell voltage will greatly increase when current flows at low frequency, even at the Slow Wave-Sleeping (SWS). The 10 pM pyruvates in the PBS buffer alone have the second higher peak intensity in the control buffer, that indicates the device in nature is a biomimetic mitochondria cell with the pyruvate molecules direct communicates with the embedded biomimetic PDC enzyme produced a magnetic flux at current=0. We noticed pyruvate reduced the OPO voltage by 27% for with the GA medium compared with that of the PBS buffer alone, that indicates the GPA relay is not favor at low frequency, it may prefer at higher frequency, evidenced by the superconductivity at 1 kHz above in FIG. 28A to FIG. 28D. Of course, the 3D toroidal-tower multiple-layer membranes have built-in multiple types of enzymes including the native enzyme such as MMP-2 and the mitochondria chaperone of HSP60, and some biomimetic enzymes such as glucose oxidase (GOx), choline acetyltransferase (ChAT) and puruvatedehydrogenase (PDH), working together to make this system functional either at low frequency or at higher frequency based on our needs, without a need for an external microwave power supply.

A kinetic control profile measured in the PBS buffer solution was presented in 4-time intervals for the open circuit potential terminal energy at 30 s, 120 s, 960 s and 1800 s in FIG. 34. The insert depicts the curve at 1800 s with the first-order rate constant 0.0122 s⁻¹ at the s-s state having a terminal energy 0.22V at current=0. The result was agreed well with the result obtained at t=120 s. More detail results obtained for with different biomarkers in the GA medium are presented in Table 1. The control kinetic curves in the 4-time intervals in FIG. 34 show the OPO voltage is overlapping at the initial transient region between 0-100 s for the 4 curves.

Table 1 presents the results of the terminal energy of the innate HSP60/MMP-2 sensor in the presence biomarkers with or without a GA medium. The PBS buffer alone has 0.22 V in OPO with a Pseudo-first order constant 0.012 s⁻¹ indicates an embedded DET relay exists, in another words, the Cooper-pairs' Friedel-oscillation in the membrane caused such energy produced in the sensor system with the magnetic flux increase exponentially at current=0. Pyruvate 10 pM in the PBS alone produced the expected highest OPO voltage 0.33V with the slowest rate constant of 0.0064 s⁻¹ in reducing of the PBS control sample's rate by 53%, that indicates pyruvate plays a havoc in direct communicating with the embedded biomimetic enzyme of PDC, it may comprise of histidine groups of MMP-2.

### Example 11

### Conclusions

Topological superconductive and memristive nanostructured toroidal-tower array. HSP60/MMP2 devices demonstrated the topological GA media, enabled Cooper-pairs reentry between states, i.e., superconductive state and memristive state, therefore enabled the device sensing multiple biomarkers, such as glucose, pyruvate, and ACoA under antibody-free and label-free conditions. The media acted as the topological insulator; it leads Cooper-pairs jumping-diving reentry in a long-range tunneling fashion along the toroidal vortex wall. This approach paved a foundation for further quantitative analysis of complex PPI networks in a superconductor/memristor device with FFJJ and a topological media possible.

The GA valve medium turned the device to a superconductive state at zero-bias when 10 pM pyruvate in the GA medium at Josephson frequency 97 GHz produced quantum conductance 74,667-fold higher than the GA medium displayed in the 3D dynamic map showing the d-wave Cooper-pairs crossed the FFJJ in perpendicular to the Marjoram Zero-Mode (MZM) surface might provide parameters useful for researchers to study the PPI network among many known and unknown enzymes for fast screening therapeutic drugs for diseases.

What is claimed is:

1. A room-temperature topological superconductive/Mem-element protein moonlighting network device comprising:
(a) a first electrode having a first layer of an organic superconductive membrane with flexible fractional Josephson junctions (FFJJ) made of innate organometallic protein of matrix matelloproteinase-2 (MMP-2) cross-linked with conductive polymers of triacetyl-B-cyclodextrin (TCD), polyethylene glycol diglycidyl ether (PEG), poly(4-vinylpyridine) (PVP) formed toroidal arrays of nanostructure superlattices by self-assembling (SAM); and
(b) a second layer membrane comprising of an organic membrane that made of cross-linked innate Heat Shock Protein (HSP60), TCD, PEG and PVP formed arrays of nanostructure towers in a SAM, that was laid on the top of the first layer;
(c) observations of Friedel-oscillation and the Josephson vortex oscillation at the junctions in both layers' SAMs had observed; and
(d). there is a direct electron-relay in a medium comprising of glucose and acetyl CoA (AcoA), as GA medium, formed a long-range electron-relay chain when biomarker pyruvate molecules are presented, that facilitated a biomimitic glucose . . . pyruvate . . . ACoA fuel energy pathway of a known mitochondria cell when biomarkers interact with the functional groups in a 3D network protein moonlighting MMP/HSP double-layer membranes having an GA medium as a “Valve” turn-On the Cooper-pairs two-way superconducting/memristive switch in a 3D horizontal-vertical direction when a potential is applied from low Josephson frequency to high Josephson frequency; and
(e) biomarkers presence inducted mem-element of hysterisis loops at a 60 Hz low frequency in PBS solution, while a superconductive protein moonlighting network device does not have this characteristics under the same conditions.

2. According to claim 1, wherein a protein moonlighting network device has superconductivity shown a quantum conductance value increases as the scan rate increase from 60 to 20 kHz at room temperature in a PBS solution.

3. According to claim 2, wherein a linear relationship between Josephson frequency and the Shapiro Step Voltage was observed having a K_{J} value of 241.8, which defined a 4 π Josephson periodicity of the FFTJJ vortex.

4. According to claim 1, wherein a protein moonlighting network device's superconductivity value was orders of magnitude higher in 74,667-fold than that of the control when a 10 pM pyruvate presences in a GA media having superpositioning observed at 97 GHz compared at 153 GHz of the Josephson frequency.

5. According to claim 1, wherein a 1 mg/dL Glucose . . . ACoA (3 nM) medium acts as a topological insulator-like platform over scan rate 60 Hz-25 kHz to guide Cooper-pairs moving only along the edge of HSP's wall directions.

6. According to claim 1, wherein a first superlattice layer SAM has orderly toroidal arrays in 200 nm to 300 nm diameter pore size in 1 mm² area; and the thickness between 50-90 nm having pore diameters between 1.8 to 4.8 mm in a 8.9×8.9 mm² area having zinc atoms showing Friedel-oscillation was observed.

7. According to claim 1, wherein a second layer SAM have nano-tower structures with a diameter between 500 nm to 2.4 um and a height of 500 nm having 5-10% alignment with the pores in the first SAM causing Friedel-oscillation in the second layer SAM.

8. According to claim 1, wherein a GA valve medium turned the device to a superconductive state at zero-bias potential when 10 pM pyruvate presences in the medium at Josephson frequency 97 GHz produced quantum conductance of 74,667-fold higher than the control demonstrating a d-wave Cooper-pairs crossed the Flexible Fractional Josephson Junction (FFJJ) in perpendicular to the Marjoram Zero-Mode (MZM) surface.

9. According to claim 1, wherein the device in PBS solution at 60 Hz, a ratio of fractional Josephson junction's energy vs. a capacitive energy is 1.0, while when scan rate increased to 25 kHz, the ratio is higher indicating a phase change induced Josephson energy increase more than the increase of the capacitance energy at zero-bias at room temperature without a microwave magnetic power applied.

10. According to claim 1, wherein a superconductive/Mem-element protein moonlighting network device has protein moonlighting multiple-functions, including, but not limited to a native enzyme of MMP-2, protein chaperonins HSP60, a biomimetic glucose oxidase (GOx), a biomimetic pyruvate dehydrogenase (PDH), or a biomimetic choline acetyltransferase (ChAT) to attract and communicate with multiple biomarkers in a sample to be directly detected when a potential is scanned using a cyclic voltammetry method, or a constant potential is applied using a double-chronoamperometric method, without interference under antibody-free, and labeling-free conditions.

11. According to claim 1, wherein the biomarkers are glucose, choline, ACoA, and pyruvate.

12. According to claim 1, wherein a superconductive/Mem-element protein moonlighting network device's memristive characteristics with hysterisis loop switched at zero potential and zero current were observed under the induction of 60 μg/mL glucose at 60 Hz, 5 fM pyruvate at 60 Hz, and 3 nM ACoA at 20 and 60 Hz, respectively in PBS solution.

13. According to claim 1, wherein a suoperconductive/mem-element protein moonlighting network device is a sensor device for direct linearly sense glucose in clinical useful range with a DETₒₓ peak ensitivity of 0.0044 μA/(mg.(dL)⁻¹) over concentrations from 80 mg/dL to 1.0 g/dL with a relative standard error of estimation of a linear regression fitting 0.2% , and the MEM peak's sensitivity of 0.0039 μA/(mg.(dL)⁻¹) from 10 mg/dL to 800 mg/dL using a CV method at scan arte 60 Hz.

14. According to claim 1, wherein a topological superconductive/Mem-element protein moonlighting network device is a sensor device for direct sense pyruvate, its Detection of Limits (DOL) is 13 aM over a range between 5 fM to 1 μM compared with the GA control, and a Relative Pooled Standard Deviation (RPSD) value 1.4% was obtained by a CA method.

15. According to claim 1, wherein a topological superconductive/Mem-element protein moonlighting network device is a sensor device for direct sense ACoA concentration over 3 nM in the PBS buffer with memristive peaks at scan rate 60 Hz having current increased 10⁶-10⁷-fold compared with the PBS control samples indicating ACoA also direct bio-communicates with the biomimetic choline acetyltransferase (ChAT) receptors.

16. According to claim 1, wherein a topological superconductive/Mem-element protein moonlighting network device is a superconducting oscillation sensor device under 10 μM choline in PBS solution having superpositioning with multiple-states at zero-bias, indicates choline enhanced the memory and Cooper-pairs' entanglement properties of the sensor 3D cavity.

17. According to claim 1, wherein a topological superconductive/Mem-element protein moonlighting network device has a state valve guided the Cooper-pair electrons accomplished not only conducted a horizontal direction move, but also a vertically move along the HSP cavity wall at the Josephson frequencies from 97 GHz to 343 GHz with superposition at p(1, 0) and p(−1, 0) and p(0,0) state at zero-bias, while either pyruvate along or GA medium along cannot accomplish this function.
